(19) United States
(12) Patent Application Publication
(10) Pub. No.: US 2026/0313894 A1
(43) Pub. Date: Oct. 8, 2026

(54) SEMICONDUCTOR DEVICE WITH THROUGH ELECTRODE THROUGH MOLD STRUCTURE

(71) Applicant: SAMSUNG ELECTRONICS CO., LTD., Suwon-si (KR)

(72) Inventors: Myunghun LEE, Suwon-si (KR); Hyuckjoon Kwon, Suwon-si (KR); Junhyoung Kim, Suwon-si (KR); Youngseok Byeon, Suwon-si (KR)

(73) Assignee: SAMSUNG ELECTRONICS CO., LTD., Suwon-si (KR)

(21) Appl. No.: 19/456,629

(22) Filed: Jan. 22, 2026

(30) Foreign Application Priority Data
Feb. 11, 2025 (KR) 10-2025-0017515

(51) Int. Cl. H10B 43/27; H10B 41/10; H10B 41/27; H10B 41/41; H10B 43/10; H10B 43/40; H10B 80/00; H10W 80/00; H10W 90/00; H10W 90/26

(52) U.S. Cl. CPC H10B 43/27; H10B 41/10; H10B 41/27; H10B 41/41; H10B 43/10; H10B 43/40; H10B 80/00; H10W 80/312; H10W 80/327; H10W 90/26; H10W 90/792

(57) ABSTRACT

A semiconductor device including: a cell structure including: a first surface; a second surface opposite to the first surface; and a main block and a dummy block each comprising a cell region and a connection region, in which the dummy block includes: a mold structure comprising at least one gate electrode and at least one mold insulating layer in a first direction in the cell region and the connection region; a common source layer on the mold structure; a first insulating layer on the mold structure and the common source layer; a channel structure connected to the common source layer; a cell plug in contact with the at least one gate electrode; a contact structure passing through the first insulating layer; and a through electrode connected to the contact structure by passing through the mold structure in the first direction in the cell region.

### CROSS-REFERENCE TO RELATED APPLICATION

This application is based on and claims priority under 35 U.S.C. §119 to Korean Patent Application No. 10-2025-0017515, filed on February 11, 2025, in the Korean Intellectual Property Office, the disclosure of which is incorporated by reference herein in its entirety.

### BACKGROUND

The embodiments of the present disclosure relates to a semiconductor device, and more particularly, to a semiconductor device including three-dimensionally arranged memory cells.

Electronic systems requiring data storage require semiconductor devices capable of storing high volumes of data. As one of the methods of increasing the data storage capacity of a semiconductor device, a semiconductor device including three-dimensionally arranged memory cells instead of two-dimensionally arranged memory cells has been proposed. In addition, a semiconductor device in which a portion of the semiconductor device is formed on a first substrate, the other portion of the semiconductor device is formed on a second substrate, and the first substrate is bonded to the second substrate has been proposed.

### SUMMARY

The embodiments of the present disclosure provides a semiconductor device having excellent operating characteristics and improved integration.

According to an aspect of the disclosure, a semiconductor device includes: a cell structure including: a first surface; a second surface opposite to the first surface; and a main block and a dummy block each comprising a cell region and a connection region, in which the dummy block includes: a mold structure comprising at least one gate electrode and at least one mold insulating layer in a first direction in the cell region and the connection region; a common source layer on the mold structure; a first insulating layer on the mold structure and the common source layer; a channel structure connected to the common source layer by passing through the mold structure in the first direction in the cell region; a cell plug in contact with the at least one gate electrode by passing through the mold structure in the first direction in the connection region; a contact structure passing through the first insulating layer; and a through electrode connected to the contact structure by passing through the mold structure in the first direction in the cell region.

According to an aspect of the disclosure, a semiconductor device includes: a cell structure including: a first surface, a second surface opposite to the first surface, and a main block and a dummy block each comprising a cell region and a connection region, in which the dummy block includes: a mold structure comprising at least one gate electrode and at least one mold insulating layer in a first direction in the cell region and the connection region; a common source layer on the mold structure; a first insulating layer on the mold structure and the common source layer; a channel structure connected to the common source layer by passing through the mold structure in the first direction in the cell region; a cell plug in contact with the at least one gate electrode by passing through the mold structure in the first direction in the connection region; a contact structure passing through the first insulating layer; a through electrode comprising a first through electrode and a second through electrode each connected to the contact structure by passing through the mold structure in the first direction in the cell region; and an electrode isolation insulating layer between the first through electrode and the second through electrode and extending in a second direction different from the first direction through the mold structure.

According to an aspect of the disclosure, a semiconductor device includes: a peripheral circuit structure; and a cell structure including: a main block and a dummy block spaced apart from the main block in a first direction, a cell region, and a connection region, in which the dummy block includes: a mold structure comprising at least one gate electrode and at least one mold insulating in a second direction in the cell region and the connection region; a common source layer on the mold structure; a first insulating layer on the mold structure and the common source layer; a channel structure connected to the common source layer by passing through the mold structure in the second direction in the cell region; a cell plug in contact with at least one gate electrode by passing through the mold structure in the second direction in the connection region; a contact structure including a first contact passing through the first insulating layer in the cell region and a second contact connected to the cell plug by passing through the first insulating layer in the connection region; and a through electrode connecting the first contact to the peripheral circuit structure by passing through the mold structure in the second direction in the cell region.

### BRIEF DESCRIPTION OF DRAWINGS

Embodiments of the present disclosure will be more clearly understood from the following detailed description taken in conjunction with the accompanying drawings in which:

FIG. 1 is a block diagram of a semiconductor device according to embodiments;

FIG. 2 is an example circuit diagram of a memory cell array of a semiconductor device according to embodiments;

FIG. 3 is a perspective view illustrating a representative structure of a semiconductor device according to embodiments;

FIG. 4 is a plan layout diagram of a semiconductor device;

FIG. 5 is a magnified layout diagram of a portion A of FIG. 4;

FIG. 6 is a cross-sectional view of FIG. 5 taken along line X1-X1’;

FIGS. 7A and 7B are layout diagrams illustrating a semiconductor device according to embodiments;

FIGS. 8A to 8C are cross-sectional views of semiconductor devices according to embodiments;

FIG. 9 is a magnified layout diagram of a semiconductor device according to embodiments;

FIG. 10 is a cross-sectional view of FIG. 9 taken along line X2-X2’;

FIG. 11 is a layout diagram illustrating a semiconductor device according to embodiments;

FIG. 12 is a layout diagram illustrating a semiconductor device according to embodiments;

FIGS. 13 to 20 are cross-sectional views illustrating a method of manufacturing a semiconductor device, according to embodiments;

FIG. 21 is a block diagram schematically illustrating a data storage system including a semiconductor device according to embodiments;

FIG. 22 is a perspective view schematically illustrating a data storage system including a semiconductor device according to embodiments; and

FIG. 23 is a cross-sectional view schematically illustrating a semiconductor package according to embodiments.

### DETAILED DESCRIPTION OF EMBODIMENTS

Hereinafter, embodiments are described in detail with reference to the accompanying drawings. Like reference numerals in the drawings denote like elements, and thus their repetitive description will be omitted.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

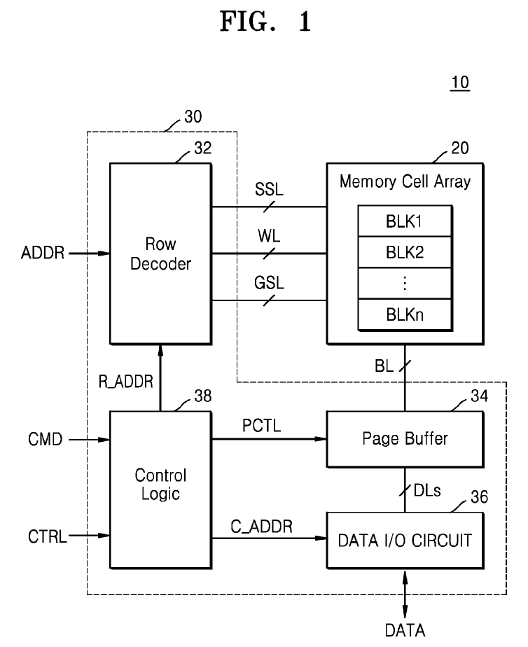

FIG. 1 is a block diagram of a semiconductor device 10 according to embodiments.

Referring to FIG. 1, the semiconductor device 10 may include a memory cell array 20 and a peripheral circuit 30. The memory cell array 20 includes a plurality of memory cell blocks BLK1, BLK2, …, and BLKn. Each of the plurality of memory cell blocks BLK1, BLK2, …, and BLKn may include a plurality of memory cells. The plurality of memory cell blocks BLK1, BLK2, …, and BLKn may be connected to the peripheral circuit 30 through a plurality of bit lines BL, a plurality of word lines WL, string select lines SSL, and ground select lines GSL.

The peripheral circuit 30 may include a row decoder 32, a page buffer 34, a data input-output circuit 36, and a control logic 38. Although not shown in FIG. 1, the peripheral circuit 30 may further include an input-output interface, a column logic, a voltage generator, a pre-decoder, a temperature sensor, a command decoder, an address decoder, an amplification circuit, or any other suitable component known to one of ordinary skill in the art.

The memory cell array 20 may be connected to the page buffer 34 through the plurality of bit lines BL and connected to the row decoder 32 through the plurality of word lines WL, the string select lines SSL, and the ground select lines GSL. In the memory cell array 20, each of a plurality of memory cells included in each of the plurality of memory cell blocks BLK1, BLK2, …, and BLKn may be a flash memory cell. The memory cell array 20 may include a three-dimensional memory cell array. The three-dimensional memory cell array may include a plurality of NAND strings, and each of the plurality of NAND strings may include a plurality of memory cells vertically stacked on a substrate and connected to the plurality of word lines WL.

The peripheral circuit 30 may receive an address ADDR, a command CMD, and a control signal CTRL from the outside of the semiconductor device 10 and transmit and receive data DATA to and from a device outside the semiconductor device 10.

The row decoder 32 may select at least one of the plurality of memory cell blocks BLK1, BLK2, …, and BLKn in response to the address ADDR from the outside and may select a word line WL, a string select line SSL, and a ground select line GSL of the selected memory cell block. The row decoder 32 may provide, to the word line WL of the selected memory cell block, a voltage for performing a memory operation.

The page buffer 34 may be connected to the memory cell array 20 through the plurality of bit lines BL. The page buffer 34 may operate as a write driver during a program operation to apply, to the plurality of bit lines BL, a voltage according to the data DATA to be stored in the memory cell array 20 and may operate as a sense amplifier during a read operation to sense the data DATA stored in the memory cell array 20. The page buffer 34 may operate in response to a control signal PCTL provided from the control logic 38.

The data input-output circuit 36 may be connected to the page buffer 34 through data lines DLs. During a program operation, the data input-output circuit 36 may receive the data DATA from a memory controller (not shown) and provide the data DATA to the page buffer 34 as program data based on a column address C_ADDR provided from the control logic 38. During a read operation, the data input-output circuit 36 may provide the data DATA stored in the page buffer 34 to the memory controller as read data based on the column address C_ADDR provided from the control logic 38.

The data input-output circuit 36 may provide an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input-output circuit 36. The control logic 38 may generate various kinds of internal control signals to be used inside the semiconductor device 10, in response to the control signal CTRL. For example, the control logic 38 may adjust voltage levels to be provided to the plurality of word lines WL and the plurality of bit lines BL during a memory operation, such as a program operation or an erase operation.

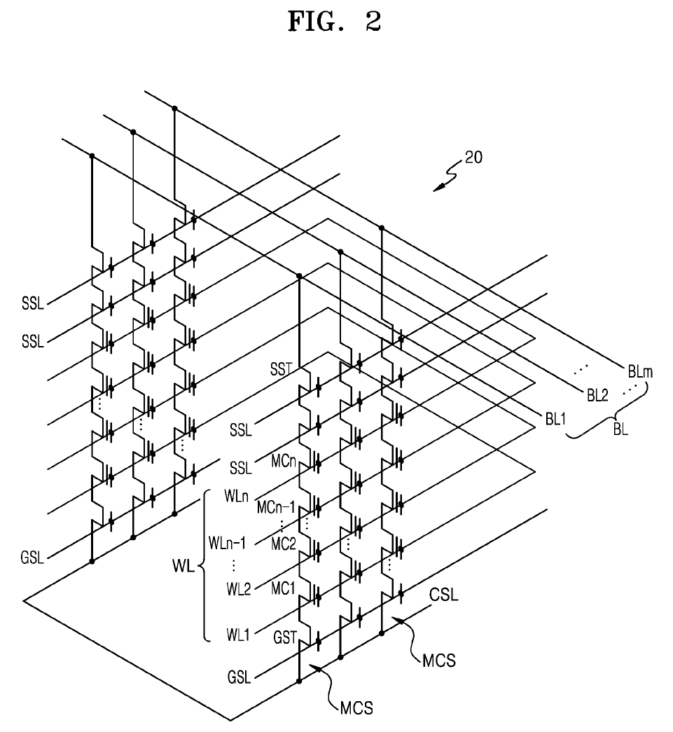

FIG. 2 is an example circuit diagram of the memory cell array 20 of the semiconductor device 10 according to embodiments.

Referring to FIG. 2, the memory cell array 20 may include a plurality of memory cell strings MCS. As understood by one of ordinary skill in the art, a memory cell string MCS may be a series of memory cells arranged in series. However, the embodiments are not limited to this configuration in which at least two memory cells in the memory cell string MCS may be connected in parallel. The memory cell array 20 may include the plurality of bit lines BL (BL1, BL2, ..., and BLm), the plurality of word lines WL (WL1, WL2, ..., WLn-1, and WLn), at least one string select line SSL, at least one ground select line GSL, and a common source line CSL. The plurality of memory cell strings MCS may be formed between the plurality of bit lines BL (BL1, BL2, ..., and BLm) and the common source line CSL. Although FIG. 2 shows that each of the plurality of memory cell strings MCS includes two string select lines SSL, the embodiments of the present disclosure are not limited to these configurations. For example, each of the plurality of memory cell strings MCS may include one string select line SSL.

Each of the plurality of memory cell strings MCS may include a string select transistor SST, a ground select transistor GST, and a plurality of memory cell transistors MC1, MC2, …, MCn-1, and MCn. A drain region of the string select transistor SST may be connected to a bit line BL (BL1, BL2, ..., or BLm), and a source region of the ground select transistor GST may be connected to the common source line CSL. The common source line CSL may be a region to which source regions of a plurality of ground select transistors GST are commonly connected.

The string select transistor SST may be connected to a string select line SSL, and the ground select transistor GST may be connected to a ground select line GSL. The plurality of memory cell transistors MC1, MC2, …, MCn-1, and MCn may be connected to the plurality of word lines WL (WL1, WL2, ..., WLn-1, and WLn), respectively.

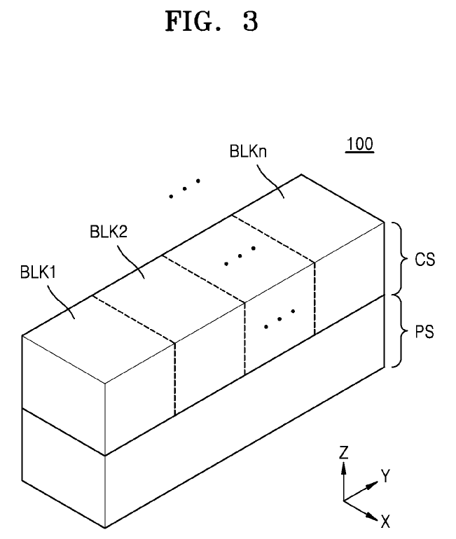

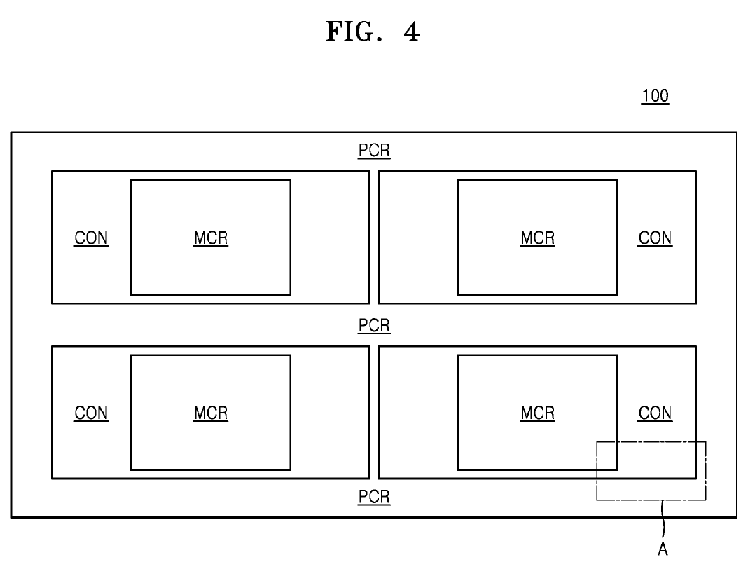

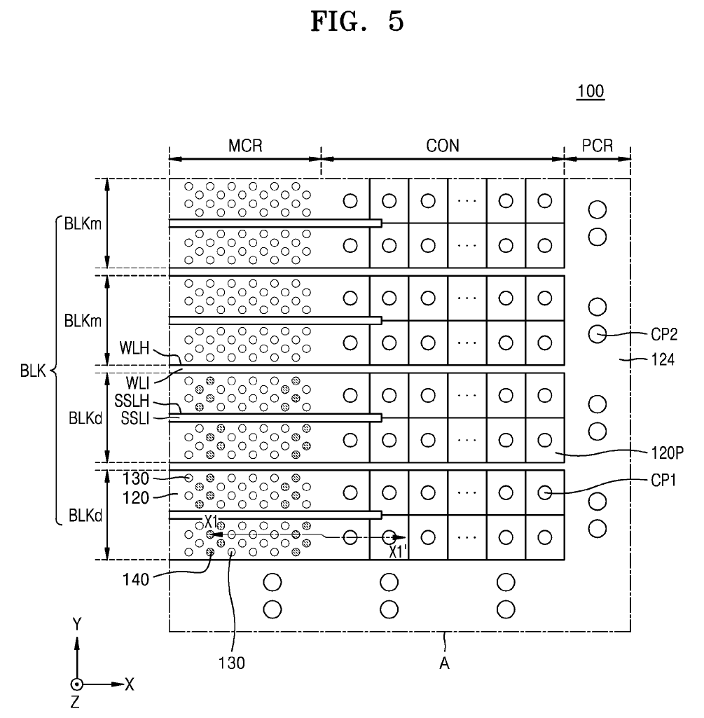

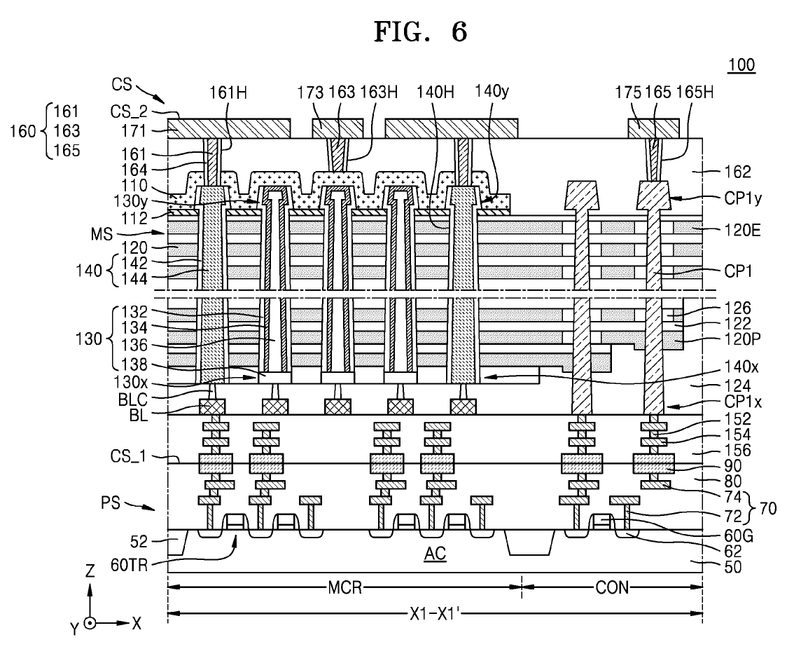

FIG. 3 is a perspective view illustrating a representative structure of a semiconductor device 100 according to embodiments. FIG. 4 is a plan layout diagram of the semiconductor device 100. FIG. 5 is a magnified layout diagram of a portion A of FIG. 4. FIG. 6 is a cross-sectional view of FIG. 5 taken along line X1-X1’.

Referring to FIGS. 3 to 6, the semiconductor device 100 may include a cell structure CS and a peripheral circuit structure PS overlapping each other in a vertical direction Z. The cell structure CS may include the memory cell array 20 described with reference to FIG. 1, and the peripheral circuit structure PS may include the peripheral circuit 30 described with reference to FIG. 1.

The cell structure CS may include the plurality of memory cell blocks BLK1, BLK2, …, and BLKn. Each of the plurality of memory cell blocks BLK1, BLK2, …, and BLKn may include three-dimensionally arranged memory cells. Each of the plurality of memory cell blocks BLK1, BLK2, …, and BLKn may have a planar shape elongated in a first horizontal direction X in a plan view.

In embodiments, a plurality of memory cell blocks BLK may include a plurality of main blocks BLKm and at least one dummy block BLKd arranged on at least one side of the plurality of main blocks BLKm. In one or more examples, a dummy block may be a circuit component that mimics the behavior of a standard memory cell but is not used for storing data. For example, the at least one dummy block BLKd may be arranged at both sides of the plurality of main blocks BLKm, but the present disclosure is not limited thereto. The at least one dummy block BLKd may be arranged between the plurality of main blocks BLKm in a second horizontal direction Y. The at least one dummy block BLKd may be formed to have the same or similar structure as or to that of the plurality of main blocks BLKm but may include a plurality of dummy memory cells which do not function as memory cells.

A plurality of stack isolation opening portions WLH elongated in the first horizontal direction X in a cell region MCR and a connection region CON may be respectively arranged between every two of the plurality of memory cell blocks BLK, and a plurality of stack isolation insulating layers WLI may be respectively arranged in the plurality of stack isolation opening portions WLH. The plurality of stack isolation insulating layers WLI may be spaced apart from each other in the second horizontal direction Y. In one or more examples, each stack isolation insulating layer WL1 may be spaced apart by an equal distance. In one or more examples, two stack isolation layers from the plurality of stack isolation insulating layers WLI may be spaced apart by a different distance than the other stack isolation insulating layers. The plurality of stack isolation opening portions WLH and the plurality of stack isolation insulating layers WL1 provide the function of isolating two memory blocks from each other.

The plurality of memory cell blocks BLK may be respectively arranged between every two of the plurality of stack isolation insulating layers WLI . Two of the plurality of stack isolation insulating layers WLI may be respectively arranged at both sides of each of the plurality of memory cell blocks BLK such that the plurality of stack isolation insulating layers WLI limit the width of each of the plurality of memory cell blocks BLK in the second horizontal direction Y. In some embodiments, gate electrodes 120 between a pair of stack isolation insulating layers WLI may constitute one memory cell block BLK.

Each of the plurality of stack isolation insulating layers WLI may have an insulating structure. In embodiments, the insulating structure may include silicon oxide, silicon nitride, silicon oxynitride, or a low dielectric material. For example, the insulating structure may include a silicon oxide layer, a silicon nitride layer, a silicon oxynitride (SiON) layer, a silicon oxycarbonitride (SiOCN) layer, a silicon carbonitride (SiCN) layer, or a combination thereof. In some embodiments, at least a portion of the insulating structure may be formed of an air gap. The term “air” used in the specification may indicate the atmosphere or other gases which may exist during a manufacturing process.

In one or more examples, at least one gate electrode 120 (e.g., the lowermost gate electrode 120) in one memory cell block BLK may be divided into two gate electrodes 120 by a string isolation opening portion SSLH. A string isolation insulating layer SSLI may be in the string isolation opening portion SSLH. The string isolation insulating layer SSLI may include an insulating layer formed of an oxide layer, a nitride layer, or a combination thereof.

The peripheral circuit structure PS may include a peripheral circuit transistor 60TR and a peripheral circuit wiring structure 70 on a substrate 50. In the substrate 50, an active region AC may be defined by a device isolation layer 52, and a plurality of peripheral circuit transistors 60TR may be formed on the active region AC. Each of the plurality of peripheral circuit transistors 60TR may include a peripheral circuit gate 60G and source/drain regions 62 at both sides of the peripheral circuit gate 60G in a portion of the substrate 50.

The substrate 50 may include a semiconductor material such as, for example, a Group IV semiconductor, a Group III-V compound semiconductor, or a Group II-VI oxide semiconductor. For example, the Group IV semiconductor may include silicon (Si), germanium (Ge), or SiGe. The substrate 50 may be provided as a bulk wafer or an epitaxial layer. In another embodiment, the substrate 50 may include a silicon-on-insulator (SOI) substrate or a germanium-on-insulator (GeOI) substrate.

The peripheral circuit wiring structure 70 may include a plurality of peripheral circuit contacts 72 and a plurality of peripheral circuit wiring layers 74. An interlayer insulating layer 80 covering the plurality of peripheral circuit transistors 60TR and the peripheral circuit wiring structure 70 may be disposed on the substrate 50. The plurality of peripheral circuit wiring layers 74 may have a multi-layer structure including a plurality of metal layers disposed at different vertical levels. A connection pad 90 may be disposed on the first interlayer insulating layer 80, and the peripheral circuit structure PS may be electrically connected and bonded to the cell structure CS by the connection pad 90.

The cell structure CS may include the cell region MCR, the connection region CON, and a peripheral circuit connection region PCR. The cell region MCR may be a region in which a memory cell block BLK including a plurality of memory cell strings extending in the vertical direction Z is arranged. Hereinafter, when the semiconductor device 100 of the present disclosure is described, the memory cell block BLK may indicate a dummy block BLKd.

In the cell region MCR, a mold structure MS, a common source layer 110 on the mold structure MS, a channel structure 130, and a through electrode 140 may be disposed. The channel structure 130 may extend in the vertical direction Z through the mold structure MS and be electrically connected to the common source layer 110. The through electrode 140 may extend in the vertical direction Z through the mold structure MS and the common source layer 110 and be electrically connected to a contact structure 160 .

In the connection region CON, extension portions 120E and pad portions 120P connected to the gate electrodes 120 and a first plug CP1 passing through extension portions 120E and a pad portion 120P and electrically connected to the pad portion 120P may be disposed. Herein, the first plug CP1 may indicate a cell plug connected to a gate electrode 120. In the peripheral circuit connection region PCR, a second plug CP2 extending in the vertical direction Z and electrically connected to the peripheral circuit wiring structure 70 may be disposed.

The cell structure CS may include a first surface CS_1 connected to the peripheral circuit structure PS and a second surface CS_2 that is opposite to the first surface CS_1. For example, the first surface CS_1 and the second surface CS_2 may be on opposite sides of the cell structure CS. FIG. 6 shows that the first surface CS_1 of the cell structure CS is at a lower side of the cell structure CS and the second surface CS_2 of the cell structure CS is at an upper side of the cell structure CS. Herein, for convenience of description, as shown in FIG. 6, it is indicated that a portion of the cell structure CS closer to the first surface CS_1 is at a lower vertical level and a portion of the cell structure CS closer to the second surface CS_2 is at a higher vertical level. For example, the aforementioned lower vertical level may be closer to the peripheral circuit structure PS than the high vertical level.

The mold structure MS may include gate electrodes 120 and mold insulating layers 122 alternately disposed in the vertical direction Z. The gate electrodes 120 may be disposed to be spaced apart from each other in the vertical direction Z, and the gate electrodes 120 may be alternately disposed with the mold insulating layers 122. The gate electrodes 120 may extend to the connection region CON, and portions of the gate electrodes 120 in the connection region CON may be referred to as extension portions 120E. The extension portions 120E may have respective horizontal lengths gradually increasing in the direction toward the second surface CS_2 of the cell structure CS (e.g., in the up direction in FIG. 6). The extension portions 120E may have a stepped shape, and the pad portions 120P may be connected to ends of the extension portions 120E, respectively. Each of the pad portions 120P may have a greater thickness than each of the extension portions 120E in the vertical direction Z.

In embodiments, the gate electrodes 120 may include a metal, such as tungsten, nickel, cobalt, or tantalum, metal silicide, such as tungsten silicide, nickel silicide, cobalt silicide, or tantalum silicide, doped polysilicon, or a combination thereof.

In embodiments, the gate electrodes 120 may correspond to the at least one ground select line GSL (see FIG. 2), the plurality of word lines WL1 to WLn (see FIG. 2), and the at least one string select line SSL (see FIG. 2) constituting a memory cell string MCS (see FIG. 2). For example, the uppermost gate electrode 120 may function as a ground select line GSL, two bottom gate electrodes 120 may function as string select lines SSL, and the remaining gate electrodes 120 may function as the plurality of word lines WL1 to WLn. Accordingly, the memory cell string MCS may be configured in which a ground select transistor GST (see FIG. 2), two string select transistors SST (see FIG. 2), and the plurality of memory cell transistors MC1 to MCn (see FIG. 2) therebetween are connected in series. In some embodiments, at least one of the gate electrodes 120 may function as a dummy word line, but the present disclosure is not limited to these configurations.

A stack insulating layer 124 may surround the gate electrodes 120, the extension portions 120E, and the pad portions 120P in the connection region CON and the peripheral circuit connection region PCR. In a plan view, the stack insulating layer 124 may surround the gate electrodes 120 and have an upper surface at the same vertical level as that of the upper surface of the uppermost gate electrode 120 in the peripheral circuit connection region PCR.

The channel structure 130 may be in a channel hole 130H extending in the vertical direction Z through the mold structure MS. The channel structure 130 may include a gate insulating layer 132, a channel layer 134, an insulating liner 136, and a drain region 138. The gate insulating layer 132, the channel hole 130H, and the insulating liner 136 may be sequentially disposed on the inner wall of the channel hole 130H.

The channel structure 130 may include a first end portion 130x disposed closer to the peripheral circuit structure PS than a second end portion 130y opposite to the first end portion 130x. In embodiments, the channel structure 130 may have an inclined sidewall having a width gradually decreasing away from the first end portion 130x. In one or more examples, the second end portion 130y may be formed to have, in a horizontal direction, a width greater than the width of a portion of the channel structure 130 passing through the mold structure MS.

The drain region 138 electrically connected to the channel layer 134 may be disposed at the first end portion 130x of the channel structure 130. The drain region 138 may be connected to a bit line contact BLC, and the channel layer 134 may be electrically connected to a bit line BL via the drain region 138 and the bit line contact BLC. At the second end portion 130y of the channel structure 130, a portion of the side surface of the channel layer 134 may not be covered by the gate insulating layer 132, and the common source layer 110 may be connected to the portion of the side surface of the channel layer 134.

The gate insulating layer 132 may have a structure sequentially including a tunneling dielectric layer, a charge storage layer, and a blocking dielectric layer on the outer wall of the channel layer 134. The tunneling dielectric layer may include silicon oxide, hafnium oxide, aluminum oxide, zirconium oxide, tantalum oxide, or any other suitable dielectric material known to one of ordinary skill in the art. The charge storage layer is a region in which electrons having passed through the tunneling dielectric layer from the channel layer 134 may be stored, and may include silicon nitride, boron nitride, silicon boron nitride, or impurity-doped polysilicon. The blocking dielectric layer may include silicon oxide, silicon nitride, or metal oxide having a greater dielectric constant than the silicon oxide. The metal oxide may include hafnium oxide, aluminum oxide, zirconium oxide, tantalum oxide, or a combination thereof.

In some embodiments, the charge storage layer may include a ferroelectric dielectric material. In one or more examples, the charge storage layer may include metal oxide having a ferroelectric material characteristic. For example, the charge storage layer may include a ferroelectric material which may store data by a hysteresis behavior due to a voltage applied to the charge storage layer . In embodiments, the charge storage layer may include at least one of hafnium oxide, zirconium oxide, and hafnium zirconium oxide.

The through electrode 140 may be in a through electrode hole 140H extending in the vertical direction Z through the mold structure MS. The through electrode 140 may pass through the mold structure MS in a dummy block BLKd. The through electrode 140 may include a through electrode insulating layer 142 and a through electrode conductive layer 144.

In embodiments, the through electrode insulating layer 142 may extend in the vertical direction Z along the through electrode hole 140H. The through electrode conductive layer 144 may extend in the vertical direction Z to fill the through electrode hole 140H on the through electrode insulating layer 142. The through electrode insulating layer 142 may be in contact with the mold structure MS in the through electrode hole 140H. Although FIG. 6 shows that the through electrode insulating layer 142 extends along only the inner wall of the through electrode hole 140H, the present disclosure is not limited thereto.

The through electrode insulating layer 142 may include a high dielectric constant material including silicon oxide, silicon nitride, silicon oxynitride, or a metal. Although FIG. 6 shows that the through electrode insulating layer 142 has a single layer, the present disclosure is not limited thereto. For example, the through electrode insulating layer 142 may include a stacked layer structure in which zirconium oxide, aluminum oxide, and zirconium oxide are sequentially stacked. The through electrode insulating layer 142 may include a dielectric layer including hafnium (Hf). The through electrode insulating layer 142 may have a stacked layer structure of a ferroelectric material layer and a paraelectric material layer.

The through electrode conductive layer 144 may be disposed on the through electrode insulating layer 142 in the through electrode hole 140H. The through electrode conductive layer 144 may extend along the through electrode insulating layer 142. The through electrode conductive layer 144 may include, for example, a doped semiconductor material, conductive metal nitride (e.g., titanium nitride, tantalum nitride, niobium nitride, tungsten nitride, or any other suitable metal nitride known to one of ordinary skill in the art), a metal (e.g., ruthenium, iridium, titanium, tantalum, or any other metal known to one of ordinary skill in the art), conductive metal oxide (e.g., iridium oxide, niobium oxide, or any other conductive metal oxide known to one of ordinary skill in the art), or any other suitable material, but is not limited thereto.

The through electrode 140 may include a first end portion 140x disposed close to the peripheral circuit structure PS and a second end portion 140y opposite to the first end portion 140x. In embodiments, the through electrode 140 may have an inclined sidewall having a width gradually decreasing away from the first end portion 140x. In one or more examples, the second end portion 140y may be formed to have, in the horizontal direction, a width greater than the width of a portion of the through electrode 140 passing through the mold structure MS.

At the first end portion 140x, the through electrode 140 may be connected to the bit line contact BLC. Particularly, the through electrode conductive layer 144 may be electrically connected to the bit line BL via the bit line contact BLC. At the second end portion 140y, the through electrode 140 may be electrically connected to the contact structure 160 by passing through the common source layer 110. Particularly, the through electrode conductive layer 144 may be electrically connected to the contact structure 160.

An etching stop layer 112 may be disposed on the uppermost gate electrode 120 and include polysilicon. In some embodiments, the etching stop layer 112 may be omitted.

The common source layer 110 may be connected to the second end portion 130y of the channel structure 130 on the etching stop layer 112. In a plan view, the common source layer 110 may be disposed on the entire region of the cell region MCR. A portion of the common source layer 110 in contact with the etching stop layer 112 may have an upper surface at a vertical level that is different from that of a portion of the common source layer 110 in contact with the second end portion 130y of the channel structure 130. In one or more examples, in some embodiments, the portion of the common source layer 110 in contact with the etching stop layer 112 may have an upper surface at a vertical level that is different from that of a portion of the common source layer 110 in contact with the second end portion 140y of the through electrode 140.

In embodiments, a first end portion CP1x of the first plug CP1 may be adjacent to the peripheral circuit structure PS, and a second end portion CP1y of the first plug CP1 may be opposite to the first end portion CP1x. The first plug CP1 may have an inclined sidewall having a width gradually decreasing away from the first end portion CP1x. In one or more examples, the second end portion CP1y may be formed to have, in the horizontal direction, a width greater than the width of a portion of the first plug CP1 passing through the mold structure MS.

In embodiments, the first plug CP1 may include a metal, such as tungsten, nickel, cobalt, or tantalum, metal nitride, such as titanium nitride, tantalum nitride, or tungsten nitride, metal silicide, such as tungsten silicide, nickel silicide, cobalt silicide, or tantalum silicide, doped polysilicon, or a combination thereof.

In the peripheral circuit connection region PCR, the second plug CP2 may be disposed to pass through the stack insulating layer 124. The shape and constituent material of the second plug CP2 may be similar to the shape and constituent material of the first plug CP1.

A connection via 152, a connection wiring layer 154, and an interlayer insulating layer 156 surrounding the connection via 152 and the connection wiring layer 154 may be disposed between the stack insulating layer 124 and the peripheral circuit structure PS. The connection via 152 and the connection wiring layer 154 may be provided with multiple layers so as to be disposed at a plurality of vertical levels, and may electrically connect the bit line BL, the first plug CP1, and the second plug CP2 to the peripheral circuit structure PS via the connection pad 90.

An upper insulating layer 162 may be disposed on the common source layer 110. The upper insulating layer 162 may have a flat upper surface all over the cell region MCR and the connection region CON. The upper insulating layer 162 may be disposed to cover the upper surface of the common source layer 110 and the upper surface of the first plug CP1.

The contact structure 160 passing through the upper insulating layer 162 may be disposed. The contact structure 160 may include a first contact 161, a second contact 165, and a common source contact 163. The first contact 161, the second contact 165, and the common source contact 163 may be spaced apart from each other in the horizontal direction (e.g., the first horizontal direction X and/or the second horizontal direction Y).

The first contact 161 may be disposed in a first contact hole 161H passing through the upper insulating layer 162 and the common source layer 110. The first contact 161 may be disposed at a position where the first contact 161 vertically overlaps the through electrode 140. The first contact 161 may be electrically connected to the through electrode conductive layer 144 of the through electrode 140. A spacer 164 may be disposed on the inner wall of the first contact hole 161H to surround the sidewall of the first contact 161. As the sidewall of the first contact 161 is surrounded by the spacer 164, the first contact 161 may be electrically isolated from the common source layer 110. In some embodiments, the upper surface of the first contact 161 may be at the same vertical level as that of the upper surface of the upper insulating layer 162.

The common source contact 163 may be disposed in a common source contact hole 163H passing through the upper insulating layer 162. The common source contact hole 163H may pass through the upper insulating layer 162 but not pass through the common source layer 110. The upper surface of the common source layer 110 may be in contact with the bottom of the common source contact hole 163H. The common source contact hole 163H may be spaced apart from the first contact hole 161H in the horizontal direction. The spacer 164 may be disposed on the inner wall of the common source contact hole 163H to surround the sidewall of the common source contact 163. In some embodiments, the upper surface of the common source contact 163 may be at the same vertical level as that of the upper surface of the upper insulating layer 162.

The second contact 165 may be disposed in a second contact hole 165H passing through the upper insulating layer 162. The second contact 165 may be disposed at a position where the second contact 165 vertically overlaps the first plug CP1. The second contact 165 may be electrically connected to the first plug CP1. The spacer 164 may be disposed on the inner wall of the second contact hole 165H to surround the sidewall of the second contact 165. In some embodiments, the upper surface of the second contact 165 may be at the same vertical level as that of the upper surface of the upper insulating layer 162.

In embodiments, a portion of the spacer 164 disposed on the inner wall of the common source contact hole 163H may be formed in the same process of forming portions of the spacer 164 disposed on the inner walls of the first contact hole 161H and the second contact hole 165H, and the common source contact 163 disposed in the common source contact hole 163H may be formed in the same process of forming the first contact 161 disposed in the first contact hole 161H and the second contact 165 disposed in the second contact hole 165H.

In embodiments, the first contact 161, the second contact 165, and the common source contact 163 may include a metal, such as tungsten, nickel, cobalt, or tantalum, metal nitride, such as titanium nitride, tantalum nitride, or tungsten nitride, metal silicide, such as tungsten silicide, nickel silicide, cobalt silicide, or tantalum silicide, or a combination thereof. In embodiments, the spacer 164 may include at least one of silicon nitride, silicon oxide, and silicon oxynitride.

A first rear wiring layer 171, a second rear wiring layer 173, and a third rear wiring layer 175 may be disposed on the upper insulating layer 162. The first rear wiring layer 171 may be electrically connected to the first contact 161. The second rear wiring layer 173 may be electrically connected to the common source contact 163. The third rear wiring layer 175 may be electrically connected to the second contact 165. The first rear wiring layer 171, the second rear wiring layer 173, and the third rear wiring layer 175 may be spaced apart from each other in the horizontal direction (e.g., the first horizontal direction X and/or the second horizontal direction Y). Although wiring layers 171, 173, and 175 are referred to as “rear” wiring layers, the embodiments of the disclosure are not limited to this configuration. For example, wiring layers 171, 173, and 175 may be referred to as “front wiring layers” or as “wiring layers.”

The first rear wiring layer 171 may be electrically connected to the peripheral circuit structure PS via the first contact 161, the through electrode 140, and the bit line BL. For example, the first rear wiring layer 171 may be configured to apply a signal and/or power from an external connection terminal to the peripheral circuit structure PS via the first contact 161, the through electrode 140, and the bit line BL. The second rear wiring layer 173 may be electrically connected to the common source layer 110 via the common source contact 163. For example, the second rear wiring layer 173 may be configured to apply a common source voltage from the external connection terminal to the common source layer 110 via the common source contact 163. The third rear wiring layer 175 may be electrically connected to the peripheral circuit structure PS via the second contact 165 and the first plug CP1. For example, the third rear wiring layer 175 may be configured to apply a signal and/or power from the external connection terminal to the peripheral circuit structure PS via the second contact 165 and the first plug CP1.

In the semiconductor device 100 of the present disclosure, the first surface CS_1 and the second surface CS_2 of the cell structure CS may be electrically connected to each other via the first contact 161 and the through electrode 140 electrically connected to the first contact 161 and passing through the mold structure MS. In one or more examples, the first surface CS_1 and the second surface CS_2 of the cell structure CS may be electrically connected to each other via the second contact 165 and the first plug CP1 electrically connected to the second contact 165. Therefore, in the semiconductor device 100 of the present disclosure, the first surface CS_1 and the second surface CS_2 of the cell structure CS may be electrically connected to each other via the through electrode 140 of the cell region MCR and the first plug CP1 of the connection region CON to directly provide a signal and power, thereby improving the electrical characteristics of the semiconductor device 100. In one or more examples, the first surface CS_1 and the second surface CS_2 of the cell structure CS may be electrically connected to each other via the through electrode 140 of the cell region MCR and the first plug CP1 of the connection region CON, thereby improving the integration of the semiconductor device 100.

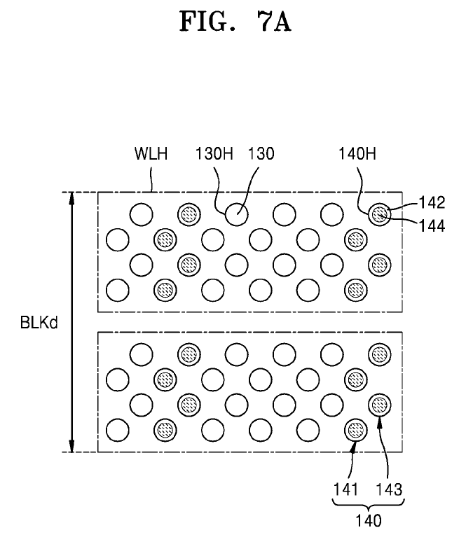

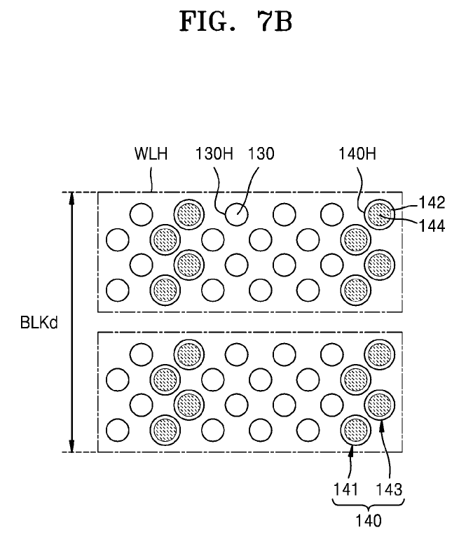

FIGS. 7A and 7B are layout diagrams illustrating the semiconductor device 100 according to embodiments.

FIGS. 7A and 7B are enlarged layout diagrams of the cell region MCR of the dummy block BLKd of the semiconductor device 100 of the present disclosure. Referring to FIGS. 7A and 7B, in the dummy block BLKd, a plurality of channel structures 130 and a plurality of through electrodes 140 may be arranged in the same shape. For example, the plurality of channel structures 130 and the plurality of through electrodes 140 may be arranged in a zigzag form. The plurality of channel structures 130 and the plurality of through electrodes 140 may be alternately arranged in the first horizontal direction X and the second horizontal direction Y. The plurality of channel structures 130 and the plurality of through electrodes 140 may be arranged in a honeycomb structure form.

In embodiments, the width of each of the plurality of channel structures 130 may be the same as the width of each of the plurality of through electrodes 140. For example, on the upper surface of the mold structure MS (see FIG. 6), the diameter of each of a plurality of channel holes 130H may be the same as the diameter of each of a plurality of through electrode holes 140H. However, the present disclosure is not limited thereto, and the diameter of each of the plurality of channel holes 130H may be different from the diameter of each of the plurality of through electrode holes 140H. For example, the diameter of each of the plurality of through electrode holes 140H may be greater than the diameter of each of the plurality of channel holes 130H. In one or more examples, the plurality of channel holes 130H may each have the same diameter. In one or more examples, at least one channel hole from the plurality of channel holes 130H may have a diameter that is different from the other channel holes. In one or more examples, the plurality of through holes 140H may each have the same diameter. In one or more examples, at least one through hole from the plurality of through holes 140H may have a diameter that is different from the other through holes. In one or more examples, the plurality of channel holes 130H and the plurality of through holes 140H may be equally distributed in the mold structure MS. In one or more examples, one portion of the mold structure MS may have a higher concentration of channel holes 130H and/or through holes 140H than another portion of the mold structure MS.

In embodiments, the through electrode 140 may include a first through electrode 141 and a second through electrode 143. The first through electrode 141 and the second through electrode 143 may be disposed in one dummy block BLKd. The first through electrode 141 and the second through electrode 143 may be arranged in a zigzag form, but the present disclosure is not limited thereto. For example, the through electrodes or the channel holes may be arranged in a straight line, concentric circles, or any other suitable pattern of arrangement.

The first through electrode 141 and the second through electrode 143 may receive different signals. For example, a plurality of first through electrodes 141 may receive a first signal, and a plurality of second through electrodes 143 may receive a second signal. The first through electrode 141 may be electrically isolated from the second through electrode 143 such that different signals are applied to the first through electrode 141 and the second through electrode 143. In one or more examples, the level of the first signal may be different from the level of the second signal. For example, the first signal may be a power source voltage, and the second signal may be a ground voltage, but the present disclosure is not limited thereto.

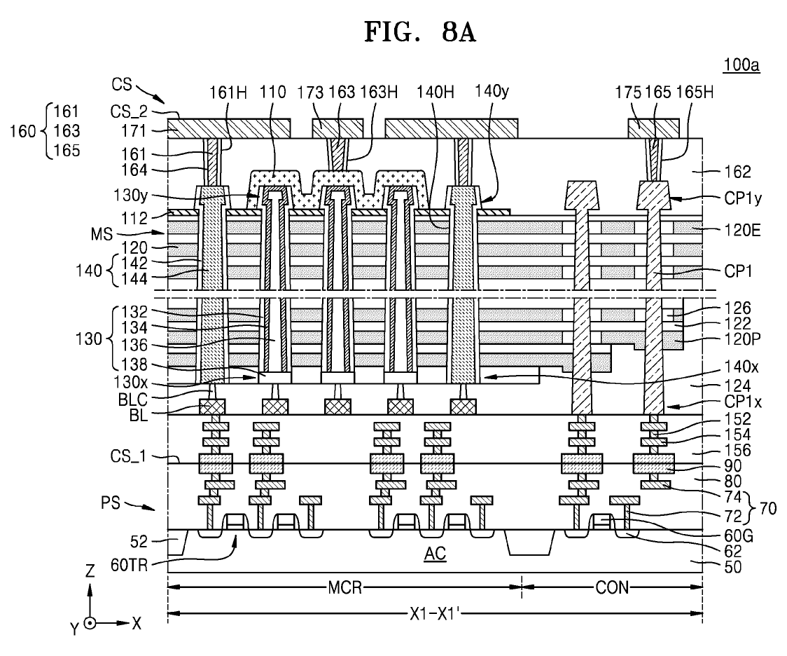

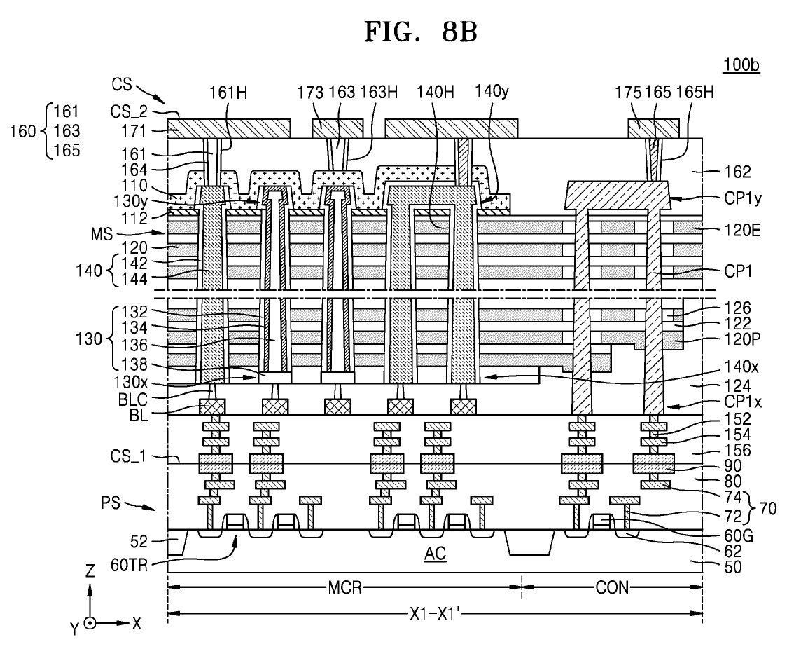

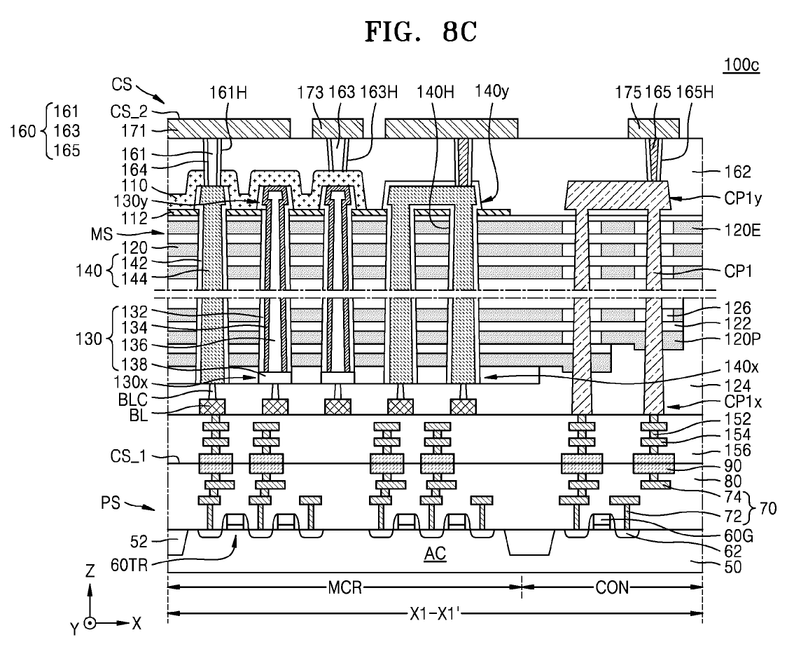

FIGS. 8A to 8C are cross-sectional views of semiconductor devices 100a, 100b, and 100c according to embodiments.

In the description of the semiconductor devices 100a, 100b, and 100c of FIGS. 8A to 8C, reference numerals in the semiconductor device 100 described with reference to FIGS. 1 to 6 denote like elements, and thus their repetitive description will be omitted, and the differences therebetween are mainly described.

Referring to FIG. 8A, in the semiconductor device 100a of the present disclosure, the common source layer 110 may not cover the second end portion 140y of the through electrode 140. At the second end portion 140y, the through electrode 140 may be electrically connected to the contact structure 160 by passing through the upper insulating layer 162. Particularly, the through electrode conductive layer 144 may be electrically connected to the contact structure 160 .

The common source layer 110 may cover the second end portion 130y of the channel structure 130 on the etching stop layer 112. The common source layer 110 may be connected to the second end portion 130y of the channel structure 130 on the etching stop layer 112. A portion of the common source layer 110 in contact with the etching stop layer 112 may have an upper surface at a vertical level that is different from that of a portion of the common source layer 110 in contact with the second end portion 130y of the channel structure 130. Referring to FIG. 8B, in the semiconductor device 100b of the present disclosure, the second end portions 140y of two or more through electrodes 140 may be merged. For example, the second end portions 140y of two through electrodes 140 adjacent to each other in the horizontal direction (e.g., the first horizontal direction X and/or the second horizontal direction Y) may be integrally formed. In one or more examples, the merged second end portion 140y of the through electrodes 140 may be electrically connected to the contact structure 160 by passing through the common source layer 110. Particularly, the merged second end portion 140y of the through electrodes 140 may be electrically connected to one first contact 161. In another embodiment, the second end portions 140y of three or more through electrodes 140 may be merged.

In embodiments, the width, in the horizontal direction (e.g., the first horizontal direction X and/or the second horizontal direction Y), of the merged second end portion 140y of the through electrodes 140 adjacent to each other may be greater than the distance between the through electrodes 140. Therefore, the first contact 161 may be connected to the merged second end portion 140y of the through electrodes 140, thereby preventing misalignment of the first contact 161 with the through electrodes 140.

In embodiments, in the semiconductor device 100b of the present disclosure, the second end portions CP1y of two or more first plugs CP1 may be merged. For example, the second end portions CP1y of two first plugs CP1 adjacent to each other in the horizontal direction (e.g., the first horizontal direction X and/or the second horizontal direction Y) may be integrally formed. In one or more examples, the merged second end portion CP1y of the first plugs CP1 may be electrically connected to the contact structure 160. Particularly, the merged second end portion CP1y of the first plugs CP1 may be electrically connected to one second contact 165.

In embodiments, the width, in the horizontal direction (e.g., the first horizontal direction X and/or the second horizontal direction Y), of the merged second end portion CP1y of the first plugs CP1 adjacent to each other may be greater than the distance between the first plugs CP1. Therefore, the second contact 165 may be connected to the merged second end portion CP1y of the first plugs CP1, thereby preventing misalignment of the second contact 165 with the first plugs CP1.

Referring to FIG. 8C, in the semiconductor device 100c of the present disclosure, the common source layer 110 may not cover the merged second end portion 140y of the through electrodes 140. The merged second end portion 140y of the through electrodes 140 may be electrically connected to the contact structure 160 by passing through the upper insulating layer 162. Particularly, the through electrode conductive layer 144 may be electrically connected to the contact structure 160 .

The common source layer 110 may cover the second end portion 130y of the channel structure 130 on the etching stop layer 112. The common source layer 110 may be connected to the second end portion 130y of the channel structure 130 on the etching stop layer 112. A portion of the common source layer 110 in contact with the etching stop layer 112 may have an upper surface at a vertical level that is different from that of a portion of the common source layer 110 in contact with the second end portion 130y of the channel structure 130.

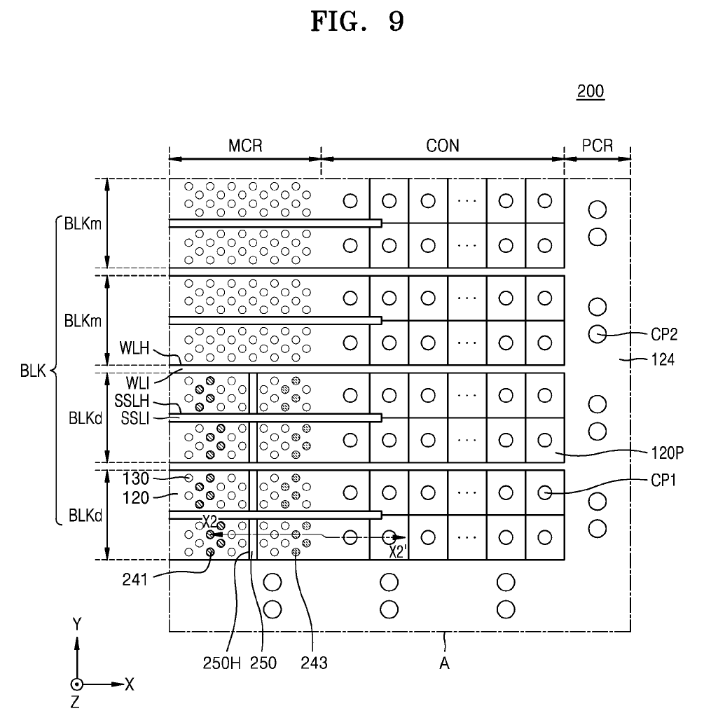

FIG. 9 is a magnified layout diagram of a semiconductor device 200 according to embodiments.

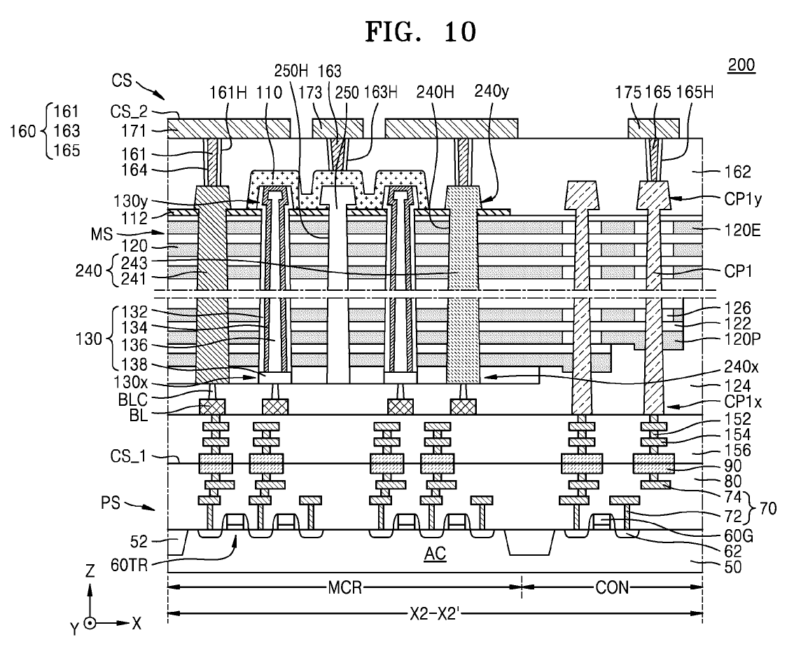

FIG. 10 is a cross-sectional view of FIG. 9 taken along line X2-X2’.

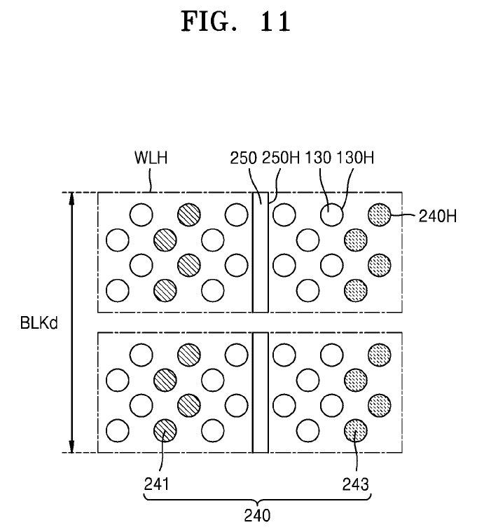

FIG. 11 is a layout diagram illustrating the semiconductor device 200 according to embodiments.

In the description of the semiconductor device 200 of FIGS. 9 to 11, reference numerals in the semiconductor device 100 described with reference to FIGS. 1 to 6 denote like elements, and thus their repetitive description will be omitted, and the differences therebetween are mainly described.

Referring to FIGS. 9 to 11, the semiconductor device 200 of the present disclosure may include a plurality of through electrodes 240 each including a first through electrode 241 and a second through electrode 243. The first through electrode 241 may be spaced apart from the second through electrode 243 with an electrode isolation insulating layer 250 therebetween. An electrode isolation opening portion 250H in a dummy block BLKd may pass through the mold structure MS in the vertical direction Z and extend in the second horizontal direction Y. The electrode isolation insulating layer 250 may fill the electrode isolation opening portion 250H and electrically isolate the first through electrode 241 from the second through electrode 243. In the dummy block BLKd, a plurality of electrode isolation insulating layers 250 may be separated from each other in the first horizontal direction X. In one or more examples, the electrode isolation insulating layer 250 may be disposed in a direction perpendicular to the plurality of stack isolation insulating layers WLI.

The electrode isolation insulating layer 250 may include an insulating structure. In embodiments, the insulating structure may include silicon oxide, silicon nitride, silicon oxynitride, or a low dielectric material. For example, the insulating structure may include a silicon oxide layer, a silicon nitride layer, a SiON layer, a SiOCN layer, a SiCN layer, or a combination thereof.

A through electrode 240 may be in a through electrode hole 240H extending in the vertical direction Z through the mold structure MS. The through electrode 240 may pass through the mold structure MS in the dummy block BLKd. The through electrode 240 may extent in the vertical direction Z along the through electrode hole 240H.

The through electrode 240 may include, for example, a doped semiconductor material, conductive metal nitride (e.g., titanium nitride, tantalum nitride, niobium nitride, tungsten nitride, or any other suitable metal nitride known to one of ordinary skill in the art), a metal (e.g., ruthenium, iridium, titanium, tantalum, or any other suitable metal known to one of ordinary skill in the art), conductive metal oxide (e.g., iridium oxide, niobium oxide, or any other suitable conductive metal oxide), or any other suitable material, but is not limited thereto.

The through electrode 240 may include a first end portion 240x disposed close to the peripheral circuit structure PS and a second end portion 240y opposite to the first end portion 240x. In embodiments, the through electrode 240 may have an inclined sidewall having a width gradually decreasing away from the first end portion 240x. In one or more examples, the second end portion 240y may be formed to have, in the horizontal direction, a width greater than the width of a portion of the through electrode 240 passing through the mold structure MS. At the first end portion 240x, the through electrode 240 may be connected to the bit line contact BLC. At the second end portion 240y, the through electrode 240 may be electrically connected to the contact structure 160 by passing through the common source layer 110.

In embodiments, in the dummy block BLKd, the plurality of channel structures 130 and the plurality of through electrodes 240 may be arranged in the same shape. For example, the plurality of channel structures 130 and the plurality of through electrodes 240 may be arranged in a zigzag form. The plurality of channel structures 130 and the plurality of through electrodes 240 may be alternately arranged in the first horizontal direction X and the second horizontal direction Y. The plurality of channel structures 130 and the plurality of through electrodes 240 may be arranged in a honeycomb structure form. For example, a plurality of first through electrodes 241 and the plurality of channel structures 130 may be spaced apart from each other in a honeycomb structure form in the horizontal direction, and a plurality of second through electrodes 243 and the plurality of channel structures 130 may be spaced apart from each other in a honeycomb structure form in the horizontal direction.

In embodiments, the width of each of the plurality of channel structures 130 may be the same as the width of each of the plurality of through electrodes 240. For example, on the upper surface of the mold structure MS (see FIG. 10), the diameter of each of the plurality of channel holes 130H may be the same as the diameter of each of a plurality of through electrode holes 240H. However, the present disclosure is not limited thereto, and the diameter of each of the plurality of channel holes 130H may be different from the diameter of each of the plurality of through electrode holes 240H. For example, the diameter of each of the plurality of through electrode holes 240H may be greater than the diameter of each of the plurality of channel holes 130H. In one or more examples, the plurality of through holes 240H may each have the same diameter. In one or more examples, at least one through hole from the plurality of through holes 140H may have a diameter that is different from the other through holes. In one or more examples, the plurality of channel holes 130H and the plurality of through holes 240H may be equally distributed in the mold structure MS. In one or more examples, one portion of the mold structure MS may have a higher concentration of channel holes 130H and/or through holes 240H than another portion of the mold structure MS.

In embodiments, the first through electrode 241 may be spaced apart from the second through electrode 243 with the electrode isolation insulating layer 250 therebetween. By the electrode isolation insulating layer 250, the first through electrode 241 may be electrically isolated from the second through electrode 243. The plurality of first through electrodes 241 and the plurality of second through electrodes 243 may be arranged in a zigzag form, but the present disclosure is not limited thereto.

The first through electrode 241 and the second through electrode 243 may receive different signals. For example, the plurality of first through electrodes 241 may receive a first signal, and the plurality of second through electrodes 143 may receive a second signal. The first through electrode 241 may be electrically isolated from the second through electrode 243 by the electrode isolation insulating layer 250 such that different signals are applied to the first through electrode 241 and the second through electrode 243. In one or more examples, the level of the first signal may be different from the level of the second signal. For example, the first signal may be a power source voltage, and the second signal may be a ground signal, but the present disclosure is not limited thereto.

The first rear wiring layer 171 may be electrically connected to the peripheral circuit structure PS via the first contact 161, the through electrode 240, and the bit line BL. For example, the first rear wiring layer 171 may be configured to apply a signal and/or power from an external connection terminal to the peripheral circuit structure PS via the first contact 161, the first through electrode 241, and the bit line BL. In one or more examples, the first rear wiring layer 171 may be configured to apply a signal and/or power from the external connection terminal to the peripheral circuit structure PS via the first contact 161, the second through electrode 243, and the bit line BL. The second rear wiring layer 173 may be electrically connected to the common source layer 110 via the common source contact 163. For example, the second rear wiring layer 173 may be configured to apply a common source voltage from the external connection terminal to the common source layer 110 via the common source contact 163. The third rear wiring layer 175 may be electrically connected to the peripheral circuit structure PS via the second contact 165 and the first plug CP1. For example, the third rear wiring layer 175 may be configured to apply a signal and/or power from the external connection terminal to the peripheral circuit structure PS via the second contact 165 and the first plug CP1.

In the semiconductor device 200 of the present disclosure, the first surface CS_1 and the second surface CS_2 of the cell structure CS may be electrically connected to each other via the first contact 161 and the through electrode 240 electrically connected to the first contact 161 and passing through the mold structure MS. In one or more examples, the first surface CS_1 and the second surface CS_2 of the cell structure CS may be electrically connected to each other via the second contact 165 and the first plug CP1 electrically connected to the second contact 165. Therefore, in the semiconductor device 200 of the present disclosure, the first surface CS_1 and the second surface CS_2 of the cell structure CS may be electrically connected to each other via the through electrode 240 of the cell region MCR and the first plug CP1 of the connection region CON to directly provide a signal and power, thereby improving the electrical characteristics of the semiconductor device 200. In one or more examples, the first surface CS_1 and the second surface CS_2 of the cell structure CS may be electrically connected to each other via the through electrode 240 of the cell region MCR and the first plug CP1 of the connection region CON, thereby improving the integration of the semiconductor device 200.

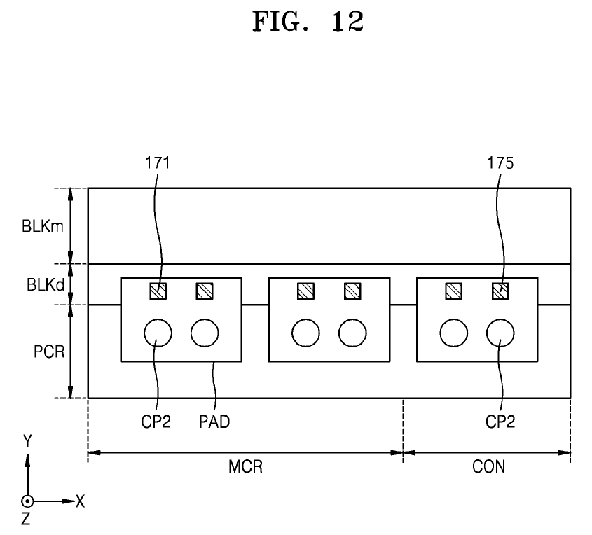

FIG. 12 is a layout diagram illustrating a semiconductor device according to embodiments.

The semiconductor device described with reference to FIG. 12 may include at least one of the semiconductor devices 100, 100a, 100b, 100c, and 200 described with reference to FIGS. 1 to 11. The semiconductor device 100, 100a, 100b, 100c, or 200 of the present disclosure may include an input-output pad PAD connecting the cell region MCR of a dummy block BLKd to the peripheral circuit connection region PCR. In one or more examples, the semiconductor device 100, 100a, 100b, 100c, or 200 may include an input-output pad PAD connecting the connection region CON of the dummy block BLKd to the peripheral circuit connection region PCR.

The input-output pad PAD may electrically connect the cell region MCR of the dummy block BLKd to the peripheral circuit connection region PCR. For example, the first rear wiring layer 171 of the cell region MCR may be electrically connected to the second plug CP2 of the peripheral circuit connection region PCR via the input-output pad PAD. The input-output pad PAD may electrically connect the connection region CON of the dummy block BLKd to the peripheral circuit connection region PCR. For example, the third rear wiring layer 175 of the connection region CON may be electrically connected to the second plug CP2 of the peripheral circuit connection region PCR via the input-output pad PAD.

The input-output pad PAD may be disposed to overlap the cell region MCR and the connection region CON of the dummy block BLKd in the vertical direction Z. For example, the input-output pad PAD may be disposed such that a partial region of the input-output pad PAD overlaps at least one dummy block BLKd in the vertical direction Z. In another embodiment, the input-output pad PAD may be disposed such that the entire region of the input-output pad PAD vertically overlaps the dummy block BLKd.

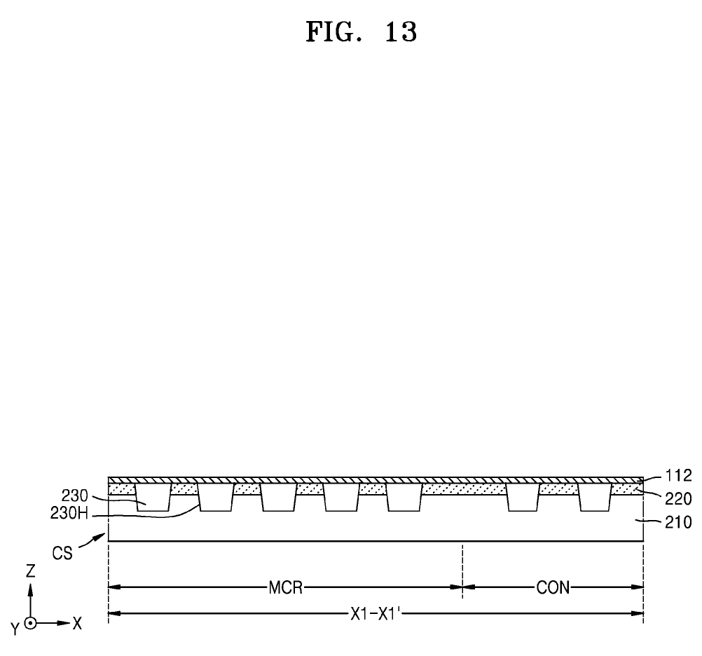

FIGS. 13 to 20 are cross-sectional views illustrating a method of manufacturing a semiconductor device, according to embodiments.

Referring to FIG. 13, a buffer insulating layer 220 may be formed on a cell substrate 210, and a portion of the cell substrate 210 and a portion of the buffer insulating layer 220 may be removed to form an opening portion 230H. Therefore, a sacrificial layer 230 may be formed in the opening portion 230H, and the etching stop layer 112 covering the sacrificial layer 230 may be formed on the buffer insulating layer 220.

In embodiments, the cell substrate 210 may include at least one of Si, Ge, SiGe, gallium arsenide (GaAs), indium gallium arsenide (InGaAs), aluminum gallium arsenide (AlGaAs), and a mixture thereof. The buffer insulating layer 220 may be formed using silicon oxide. In embodiments, the etching stop layer 112 may be formed using polysilicon. In embodiments, the sacrificial layer 230 may be formed using a metal, such as tungsten, nickel, cobalt, or tantalum, metal nitride, such as titanium nitride, tantalum nitride, or tungsten nitride, metal silicide, such as tungsten silicide, nickel silicide, cobalt silicide, or tantalum silicide, or a combination thereof.

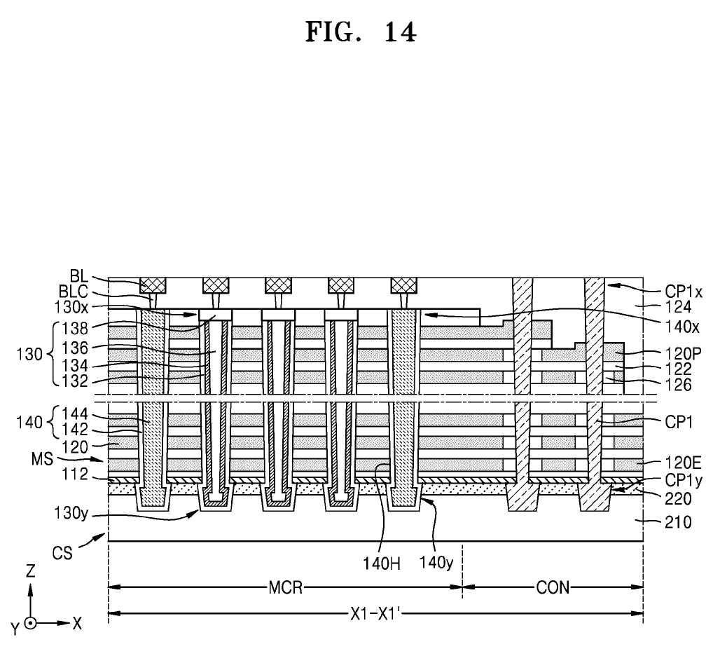

Referring to FIG. 14, in the cell region MCR and the connection region CON, the gate electrodes 120 and the mold insulating layers 122 may be alternately formed, and in the connection region CON, the extension portions 120E and the pad portions 120P connected to the gate electrodes 120 may be formed. The gate electrodes 120 and the mold insulating layers 122 may constitute the mold structure MS. In one or more examples, in the cell region MCR, the channel structure 130 and the through electrode 140 extending in the vertical direction Z through the mold structure MS may be formed, and the bit line BL connected to the channel structure 130 and the through electrode 140 may be formed. In one or more examples, in the connection region CON, the first plug CP1 passing through extension portions 120E and a pad portion 120P may be formed.

In embodiments, in a process of forming the gate electrodes 120 and the pad portions 120P, in the cell region MCR and the connection region CON, a mold stack alternately including the sacrificial layers 230 (see FIG. 13) and the mold insulating layers 122 may be formed on the etching stop layer 112, and in the connection region CON, preliminary pad portions may be formed by patterning portions of the mold stack, then the sacrificial layers 230 and the preliminary pad portions may be removed, and the gate electrodes 120 and the pad portions 120P may be formed in spaces from which the sacrificial layers 230 and the preliminary pad portions are removed.

In embodiments, in a process of forming the channel structure 130, in the cell region MCR, the channel hole 130H passing through the mold stack may be formed. In one or more examples, the sacrificial layer 230 in the opening portion 230H (see FIG. 13) may be removed, and the channel hole 130H may extend to the opening portion 230H through the etching stop layer 112. The gate insulating layer 132, the channel layer 134, and the insulating liner 136 may be sequentially formed on the inner wall of the channel hole 130H, and the drain region 138 may be formed at the entrance of the channel hole 130H.

The first end portion 130x of the channel structure 130 may be at a vertical level that is higher than that of the second end portion 130y, and the second end portion 130y may be formed to extend into the cell substrate 210 through the etching stop layer 112. The second end portion 130y may be formed to have, in the horizontal direction, a width greater than the width of a portion of the channel structure 130 passing through the mold structure MS.

In embodiments, in a process of forming the through electrode 140, the through electrode hole 140H passing through the mold stack may be formed in the cell region MCR. In one or more examples, the sacrificial layer 230 in the opening portion 230H may be removed, and the through electrode hole 140H may extend to the opening portion 230H through the etching stop layer 112. The through electrode insulating layer 142 and the through electrode conductive layer 144 may be sequentially formed on the inner wall of the through electrode hole 140H.

The first end portion 140x of the through electrode 140 may be at a vertical level that is higher than that of the second end portion 140y, and the second end portion 140y may be formed to extend into the cell substrate 210 through the etching stop layer 112. The second end portion 140y may be formed to have, in the horizontal direction, a width greater than the width of a portion of the through electrode 140 passing through the mold structure MS.

In embodiments, in a process of forming the first plug CP1, the second end portion CP1y of the first plug CP1 may be formed to have, in the horizontal direction, a width greater than the width of a portion of the first plug CP1 passing through the mold structure MS. The second end portion CP1y of the first plug CP1 may be formed to have a large height so as to extend into the cell substrate 210 through the etching stop layer 112. In embodiments, in the connection region CON, a first plug hole CP1H passing through the mold stack may be formed, a portion of the sacrificial layer 230 exposed through the sidewall of the first plug hole CP1H may be removed by lateral etching, and an insulating pattern 126 may be formed at a portion where the sacrificial layer 230 has been removed. Thereafter, the first plug CP1 may be formed in the first plug hole CP1H. A process of forming the first plug CP1 may be simultaneously performed with a process of forming the through electrode 140, but the present disclosure is not limited thereto.

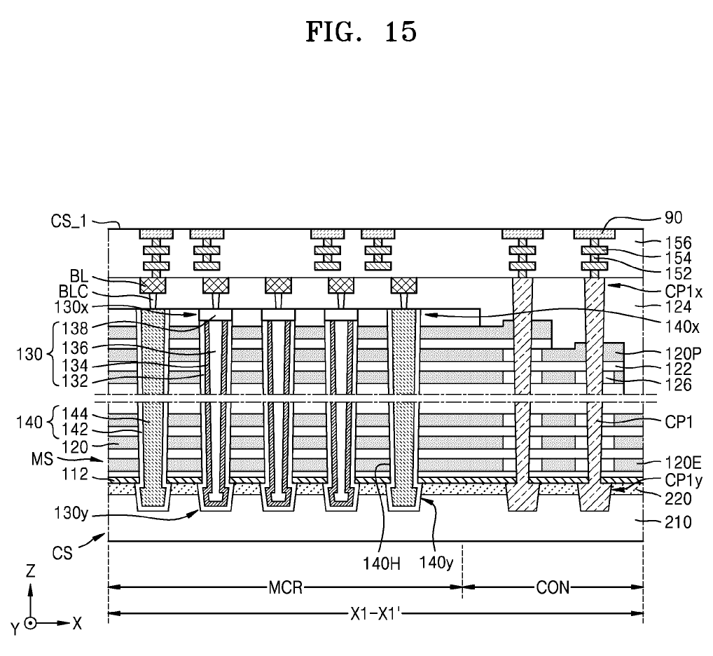

Referring to FIG. 15, the connection via 152 and the connection wiring layer 154 electrically connected to the bit line BL or the first plug CP1, and the interlayer insulating layer 156 may be formed. The connection pad 90 may be formed on the upper surface of the interlayer insulating layer 156.

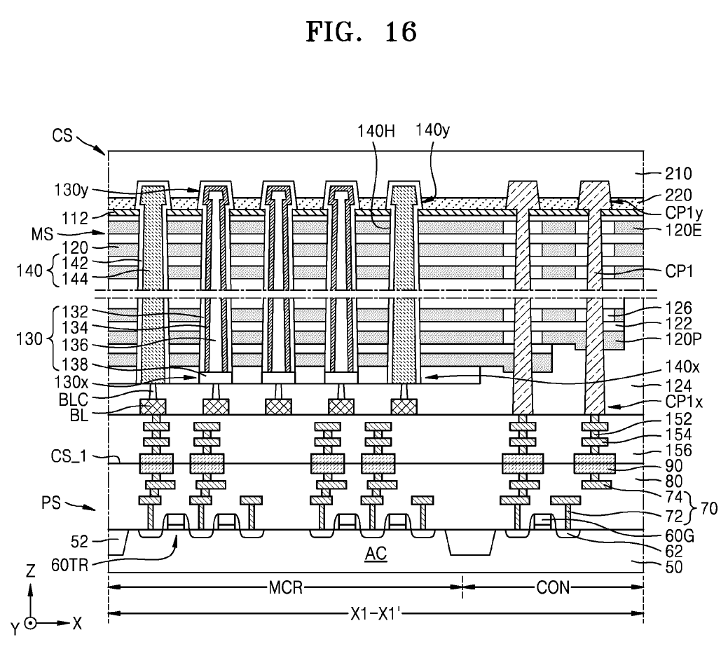

Referring to FIG. 16, the peripheral circuit structure PS may be prepared. The peripheral circuit structure PS may include the peripheral circuit transistor 60TR and the peripheral circuit wiring structure 70 on the substrate 50. In the substrate 50, the active region AC may be defined by the device isolation layer 52, and a plurality of peripheral circuit transistors 60TR may be formed on the active region AC. Each of the plurality of peripheral circuit transistors 60TR may include the peripheral circuit gate 60G and the source/drain regions 62 at both sides of the peripheral circuit gate 60G in a portion of the substrate 50.

Thereafter, the peripheral circuit structure PS may be attached to the cell structure CS. The peripheral circuit structure PS and the cell structure CS may be attached by metal-oxide hybrid bonding using the connection pad 90 and the interlayer insulating layers 80 and 156 but are not limited thereto.

Thereafter, a structure in which the peripheral circuit structure PS is attached to the cell structure CS may be upside down such that the cell substrate 210 faces upward.

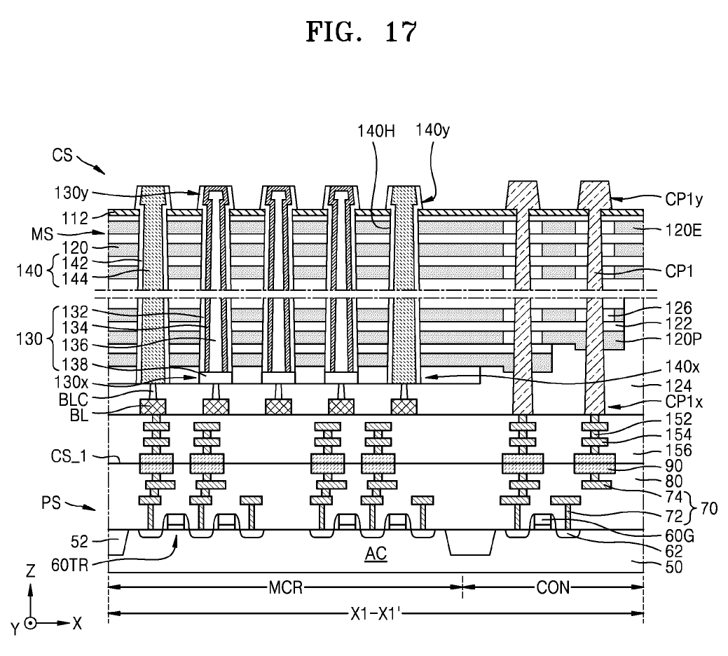

Referring to FIG. 17, the cell substrate 210 (see FIG. 16) may be removed. The cell substrate 210 may be removed by a grinding process and a subsequent etching process, and the buffer insulating layer 220 (see FIG. 16) may be exposed.

Thereafter, the buffer insulating layer 220 may also be removed, and the upper surface of the etching stop layer 112 may be exposed. As the buffer insulating layer 220 is removed, the second end portion 130y of the channel structure 130, the second end portion 140y of the through electrode 140, and the second end portion CP1y of the first plug CP1 may protrude from the upper surface of the etching stop layer 112.

Thereafter, an exposed portion of the gate insulating layer 132 at the second end portion 130y of the channel structure 130 may be removed to expose the upper surface of the channel layer 134.

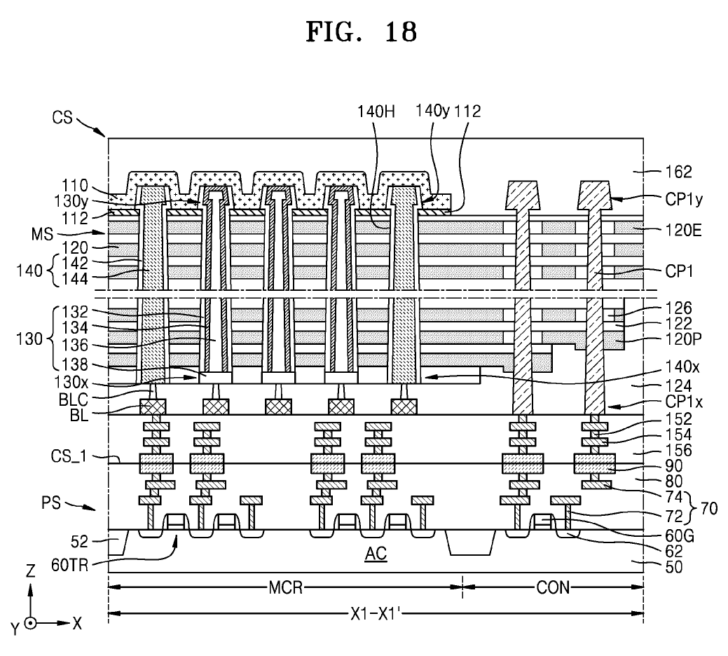

Referring to FIG. 18, the common source layer 110 may be formed in the cell region MCR and the connection region CON. The common source layer 110 may be formed using polysilicon. For example, the common source layer 110 may be formed using polysilicon doped with n-type impurities. In the cell region MCR, the common source layer 110 may be conformally formed on the etching stop layer 112 and the exposed upper surface of the channel layer 134. In the connection region CON, the common source layer 110 may cover the second end portion CP1y of the first plug CP1.

Thereafter, a portion of the common source layer 110 and a portion of the etching stop layer 112, which are disposed in the connection region CON, may be removed. In embodiments, in the cell region MCR, a mask pattern may be formed on the common source layer 110 and used as an etching mask to remove the portions of the common source layer 110 and the etching stop layer 112 in the connection region CON. As the portions of the common source layer 110 and the etching stop layer 112 in the connection region CON are removed, the second end portion CP1y of the first plug CP1 and the uppermost mold insulating layer 122 may be exposed again.

Thereafter, in the cell region MCR and the connection region CON, the upper insulating layer 162 may be formed on the common source layer 110 and the uppermost mold insulating layer 122. The upper insulating layer 162 may be formed with a sufficiently large height to fully cover the common source layer 110 and the second end portion CP1y of the first plug CP1 and have a flat upper surface level.

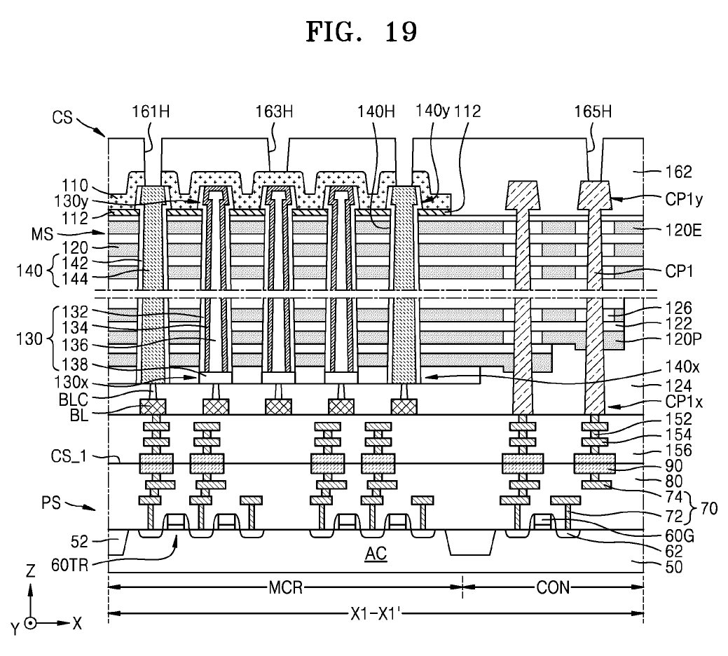

Referring to FIG. 19, a mask pattern may be formed on the upper insulating layer 162 and used as an etching mask to remove a portion of the upper insulating layer 162, thereby forming the first contact hole 161H, the second contact hole 165H, and the common source contact hole 163H. The first contact hole 161H may be formed at a position where the first contact hole 161H vertically overlaps the through electrode 140, and the second contact hole 165H may be formed at a position where the second contact hole 165H vertically overlaps the first plug CP1. In one or more examples, a portion of the through electrode insulating layer 142 exposed at the second end portion 140y of the through electrode 140 may be removed to expose the upper surface of the through electrode conductive layer 144.

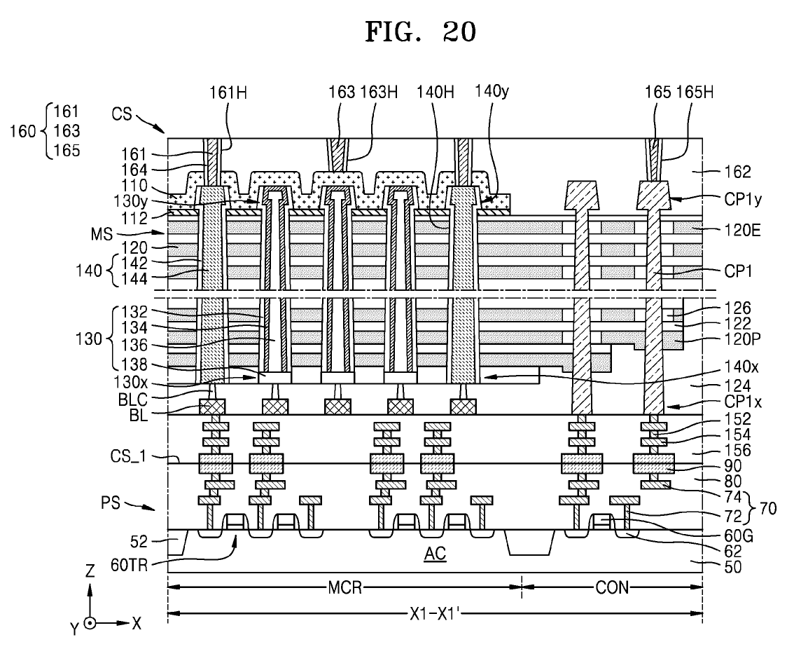

Referring to FIG. 20, the first contact 161, the second contact 165, and the common source contact 163 may be formed in the first contact hole 161H, the second contact hole 165H, and the common source contact hole 163H, respectively. The spacer 164 may be formed in each of the first contact hole 161H, the second contact hole 165H, and the common source contact hole 163H, and a conductive layer covering the spacer 164 may be formed. The top of the conductive layer may be flattened to form the first contact 161, the second contact 165, and the common source contact 163. Accordingly, the first contact 161, the second contact 165, and the common source contact 163 may include upper surfaces at the same vertical level as that of the upper surface of the upper insulating layer 162.

Referring back to FIG. 6, the first rear wiring layer 171, the second rear wiring layer 173, and the third rear wiring layer 175 may be formed on the upper insulating layer 162. The first rear wiring layer 171 may be electrically connected to the first contact 161, the second rear wiring layer 173 may be electrically connected to the common source contact 163, and the third rear wiring layer 175 may be electrically connected to the first plug CP1.

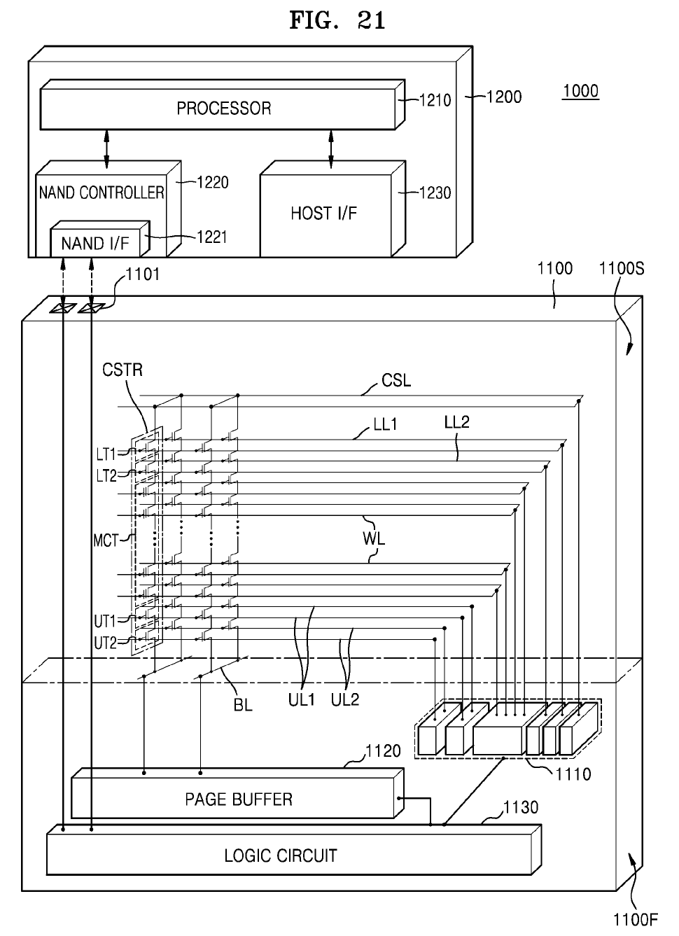

FIG. 21 is a block diagram schematically illustrating a data storage system 1000 including a semiconductor device according to embodiments.

Referring to FIG. 21, the data storage system 1000 may include one or more semiconductor devices 1100 and a memory controller 1200 electrically connected to the one or more semiconductor devices 1100. The data storage system 1000 may be, for example, a solid state drive (SSD) device, a universal serial bus (USB) device, a computing system, a medical device, or a communication device including at least one semiconductor device 1100.

A semiconductor device 1100 may be a non-volatile memory device, and for example, the semiconductor device 1100 may be a NAND flash semiconductor device including one of the semiconductor devices 10, 100, 100a, 100b, 100c, and 200 described with reference to FIGS. 1 to 12. However, as understood by one of ordinary skill in the art, the embodiments are not limited to these configurations. For examples, the embodiments of the present application may be applied to any suitable memory structure known to one of ordinary skill in the art. The semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including the bit lines BL, the common source line CSL, the plurality of word lines WL, first and second string select lines UL1 and UL2, first and second ground select lines LL1 and LL2, and a plurality of memory cell strings CSTR between the plurality of bit lines BL and the common source line CSL.

In the second structure 1100S, each of the plurality of memory cell strings CSTR may include ground select transistors LT1 and LT2 adjacent to the common source line CSL, string select transistors UT1 and UT2 adjacent to a bit line BL, and a plurality of memory cell transistors MCT between the ground select transistors LT1 and LT2 and the string select transistors UT1 and UT2. The number of ground select transistors (e.g., LT1 and LT2) and the number of string select transistors (e.g., UT1 and UT2) may be variously modified according to embodiments.

In embodiments, the first and second ground select lines LL1 and LL2 may be connected to the gate electrodes of the ground select transistors LT1 and LT2, respectively. The plurality of word lines WL may be connected to the gate electrodes of the plurality of memory cell transistors MCT, respectively. The first and second string select lines UL1 and UL2 may be connected to the gate electrodes of the string select transistors UT1 and UT2, respectively.

The common source line CSL, the first and second ground select lines LL1 and LL2, the plurality of word lines WL, and the first and second string select lines UL1 and UL2 may be connected to the row decoder 1110. The plurality of bit lines BL may be electrically connected to the page buffer 1120.

The semiconductor device 1100 may communicate with the memory controller 1200 through input-output pads 1101 electrically connected to the logic circuit 1130. The input-output pads 1101 may be electrically connected to the logic circuit 1130.

The memory controller 1200 may include a processor 1210, a NAND controller 1220, and a host interface 1230. In some embodiments, the data storage system 1000 may include a plurality of semiconductor devices 1100, and In one or more examples, the memory controller 1200 may control the plurality of semiconductor devices 1100.

The processor 1210 may control a general operation of the data storage system 1000 including the memory controller 1200. The processor 1210 may operate according to certain firmware and control the NAND controller 1220 to access the semiconductor device 1100. The NAND controller 1220 may include a NAND interface 1221 configured to process communication with the semiconductor device 1100. Through the NAND interface 1221, a control command for controlling the semiconductor device 1100, data to be written on the plurality of memory cell transistors MCT in the semiconductor device 1100, data read from the plurality of memory cell transistors MCT in the semiconductor device 1100, or any other suitable data may be transferred. The host interface 1230 may provide a communication function between the data storage system 1000 and an external host. When a control command is received from the external host through the host interface 1230, the processor 1210 may control the semiconductor device 1100 in response to the control command.

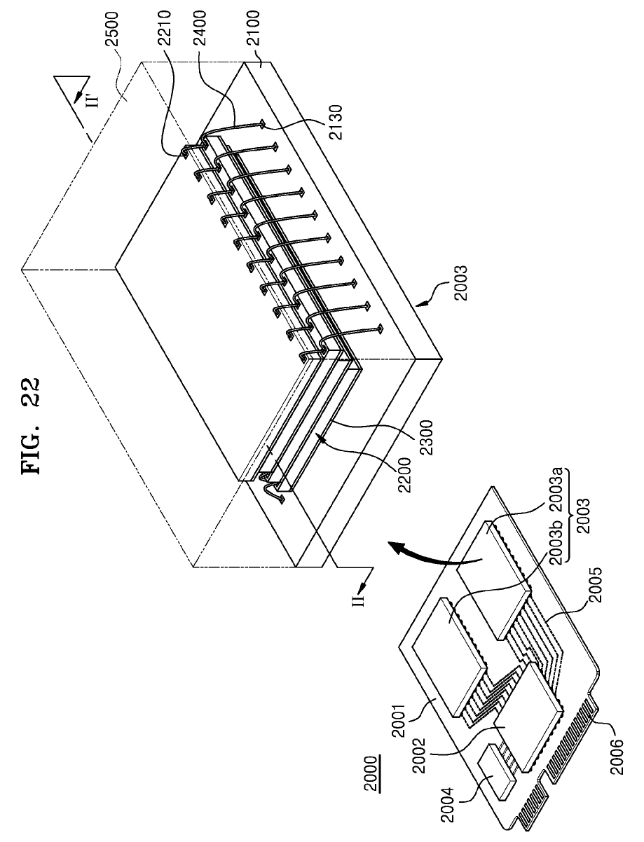

FIG. 22 is a perspective view schematically illustrating a data storage system 2000 including a semiconductor device according to embodiments.

Referring to FIG. 22, the data storage system 2000 according to one or more embodiments may include a main substrate 2001 and a memory controller 2002, a semiconductor package 2003, and dynamic random access memory (DRAM) 2004, which are mounted on the main substrate 2001. The semiconductor package 2003 and the DRAM 2004 may be connected to the memory controller 2002 through a plurality of wiring patterns 2005 formed on the main substrate 2001.

The main substrate 2001 may include a connector 2006 including a plurality of pins coupled to an external host. The number and arrangement of pins in the connector 2006 may vary according to a communication interface between the data storage system 2000 and the external host. In embodiments, the data storage system 2000 may communicate with the external host according to any one of interfaces, such as a USB interface, a peripheral component interconnect express (PCI-Express) interface, a serial advanced technology attachment (SATA) interface, and an M-Phy interface for a universal flash storage (UFS). In embodiments, the data storage system 2000 may operate by power received from the external host through the connector 2006. The data storage system 2000 may further include a power management integrated circuit (PMIC) configured to distribute the power received from the external host to the memory controller 2002 and the semiconductor package 2003.

The memory controller 2002 may write or read data on or from the semiconductor package 2003 and improve the operating speed of the data storage system 2000.

The DRAM 2004 may be a buffer memory configured to mitigate the speed difference between the semiconductor package 2003, which is a data storage space, and the external host. The DRAM 2004 included in the data storage system 2000 may operate as a kind of cache memory and provide a space in which data is temporarily stored in a control operation on the semiconductor package 2003. When the DRAM 2004 is included in the data storage system 2000, the memory controller 2002 may further include a DRAM controller configured to control the DRAM 2004, in addition to a NAND controller configured to control the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, an adhesive layer 2300 beneath each of the plurality of semiconductor chips 2200, a plurality of connection structures 2400 electrically connecting the plurality of semiconductor chips 2200 to the package substrate 2100, and a molding layer 2500 covering the plurality of semiconductor chips 2200 and the plurality of connection structures 2400 on the package substrate 2100.

The package substrate 2100 may be a printed circuit board including a plurality of package upper pads 2130. Each of the plurality of semiconductor chips 2200 may include input-output pads 2210. The input-output pads 2210 may correspond to the input-output pads 1101 of FIG. 21. Each of the plurality of semiconductor chips 2200 may include at least one of the semiconductor devices 10, 100, 100a, 100b, 100c, and 200 described with reference to FIGS. 1 to 12.

In embodiments, the plurality of connection structures 2400 may be bonding wires electrically connecting the input-output pads 2201 to the plurality of package upper pads 2130. Therefore, in the first and second semiconductor packages 2003a and 2003b, the plurality of semiconductor chips 2200 may be electrically connected to each other by a bonding wire scheme and electrically connected to the plurality of package upper pads 2130 of the package substrate 2100. In embodiments, in the first and second semiconductor packages 2003a and 2003b, the plurality of semiconductor chips 2200 may be electrically connected to each other through a connection structure including through silicon vias (TSVs) instead of the plurality of connection structures 2400 of the bonding wire scheme.

In embodiments, the memory controller 2002 and the plurality of semiconductor chips 2200 may be included in one package. In embodiments, the memory controller 2002 and the plurality of semiconductor chips 2200 may be mounted on a separate interposer substrate other than the main substrate 2001, and the memory controller 2002 may be connected to the plurality of semiconductor chips 2200 through wirings formed on the interposer substrate.

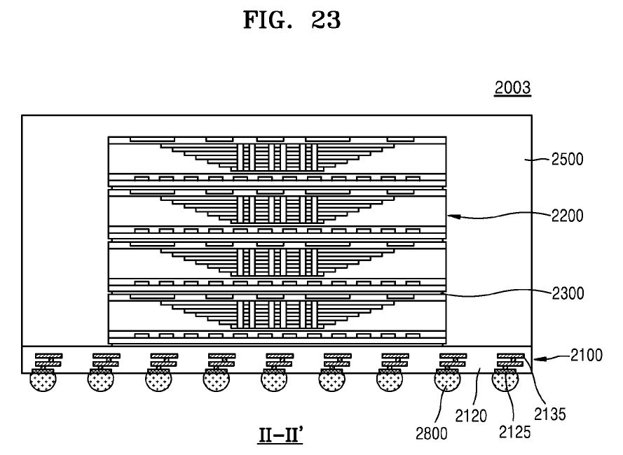

FIG. 23 is a cross-sectional view schematically illustrating a semiconductor package 2003 according to embodiments. FIG. 23 is a cross-sectional view of the semiconductor package 2003 of FIG. 22 taken along line II-II’.

Referring to FIG. 23, in the semiconductor package 2003, the package substrate 2100 may be a printed circuit board. The package substrate 2100 may include a package substrate body portion 2120, the plurality of package upper pads 2130 (see FIG. 22) on the upper surface of the package substrate body portion 2120, a plurality of lower pads 2125 disposed on or exposed through the lower surface of the package substrate body portion 2120, and a plurality of internal wirings 2135 inside the package substrate body portion 2120 to electrically connect the plurality of package upper pads 2130 (see FIG. 22) to the plurality of lower pads 2125. As shown in FIG. 22, the plurality of package upper pads 2130 may be electrically connected to the plurality of connection structures 2400, respectively. As shown in FIG. 23, the plurality of lower pads 2125 may be connected, through a plurality of conductive bumps 2800, to the plurality of wiring patterns 2005 on the main substrate 2001 of the data storage system 2000 shown in FIG. 22. Each of the plurality of semiconductor chips 2200 may include at least one of the semiconductor devices 10, 100, 100a, 100b, 100c, and 200 described with reference to FIGS. 1 to 12.

While the present disclosure has been particularly shown and described with reference to embodiments thereof, it will be understood that various changes in form and details may be made therein without departing from the spirit and scope of the following claims.

What is claimed is:

1. A semiconductor device comprising:
a cell structure comprising:
a first surface;
a second surface opposite to the first surface; and
a main block and a dummy block each comprising a cell region and a connection region,
wherein the dummy block comprises:
a mold structure comprising at least one gate electrode and at least one mold insulating layer in a first direction in the cell region and the connection region;
a common source layer on the mold structure;
a first insulating layer on the mold structure and the common source layer;
a channel structure connected to the common source layer by passing through the mold structure in the first direction in the cell region;
a cell plug in contact with the at least one gate electrode by passing through the mold structure in the first direction in the connection region;
a contact structure passing through the first insulating layer; and
a through electrode connected to the contact structure by passing through the mold structure in the first direction in the cell region.

2. The semiconductor device of claim 1, further comprising a peripheral circuit structure connected to the first surface of the cell structure,
wherein the through electrode connects the contact structure to the peripheral circuit structure.

3. The semiconductor device of claim 1, wherein the contact structure comprises:
a first contact passing through the first insulating layer in the cell region and connected to the through electrode; and
a second contact passing through the first insulating layer in the connection region and connected to the cell plug.

4. The semiconductor device of claim 3, further comprising:
a peripheral circuit structure connected to the first surface of the cell structure;
a first wiring layer connected to the peripheral circuit structure via the through electrode and the first contact; and
a second wiring layer connected to the peripheral circuit structure via the cell plug and the second contact.

5. The semiconductor device of claim 1, wherein the through electrode is connected to the contact structure by passing through a portion of the common source layer in the first direction.

6. The semiconductor device of claim 1, wherein the channel structure is in a channel hole extending in the first direction through the mold structure, the through electrode is in a through electrode hole extending in the first direction through the mold structure, and a diameter of the channel hole is the same as a diameter of the through electrode hole.

7. The semiconductor device of claim 6, wherein the through electrode comprises:
a through electrode insulating layer extending along the through electrode hole; and
a through electrode conductive layer in the through electrode hole on the through electrode insulating layer.

8. The semiconductor device of claim 1, wherein the through electrode and the channel structure are spaced apart from each other in a honeycomb structure form in a second direction perpendicular to the first direction.

9. The semiconductor device of claim 1, wherein the through electrode comprises a first through electrode and a second through electrode spaced apart from the first through electrode in a second direction perpendicular to the first direction, a first signal is applied to the first through electrode, and a second signal having a signal level that is different from that of the first signal is applied to the second through electrode.

10. The semiconductor device of claim 1, wherein end portions of two or more through electrodes are merged to form a merged end portion, and the merged end portion is connected to one contact structure.

11. A semiconductor device comprising:
a cell structure comprising:
a first surface,
a second surface opposite to the first surface, and
a main block and a dummy block each comprising a cell region and a connection region,
wherein the dummy block comprises:
a mold structure comprising at least one gate electrode and at least one mold insulating layer in a first direction in the cell region and the connection region;
a common source layer on the mold structure;
a first insulating layer on the mold structure and the common source layer;
a channel structure connected to the common source layer by passing through the mold structure in the first direction in the cell region;
a cell plug in contact with the at least one gate electrode by passing through the mold structure in the first direction in the connection region;
a contact structure passing through the first insulating layer;
a through electrode comprising a first through electrode and a second through electrode each connected to the contact structure by passing through the mold structure in the first direction in the cell region; and
an electrode isolation insulating layer between the first through electrode and the second through electrode and extending in a second direction different from the first direction through the mold structure.

12. The semiconductor device of claim 11, further comprising a peripheral circuit structure connected to the first surface of the cell structure,
wherein the through electrode connects the contact structure to the peripheral circuit structure.

13. The semiconductor device of claim 11, wherein the contact structure comprises:
a first contact passing through the first insulating layer in the cell region and connected to the through electrode; and
a second contact passing through the first insulating layer in the connection region and connected to the cell plug.

14. The semiconductor device of claim 13, further comprising:
a peripheral circuit structure connected to the first surface of the cell structure;
a first wiring layer connected to the peripheral circuit structure via the through electrode and the first contact; and
a second wiring layer connected to the peripheral circuit structure via the cell plug and the second contact.

15. The semiconductor device of claim 11, further comprising a stack isolation insulating layer extending in a third direction, which intersects the second direction, through the mold structure, and between the main block and the dummy block.

16. The semiconductor device of claim 11, wherein a first signal is applied to the first through electrode, and a second signal having a signal level that is different from that of the first signal is applied to the second through electrode.

17. The semiconductor device of claim 11, wherein the first through electrode and the channel structure are spaced apart from each other in a honeycomb structure form in the second direction, and the second through electrode and the channel structure are spaced apart from each other in the honeycomb structure form in the second direction.

18. A semiconductor device comprising:
a peripheral circuit structure; and
a cell structure comprising:
a main block and a dummy block spaced apart from the main block in a first direction,
a cell region, and
a connection region,
wherein the dummy block comprises:
a mold structure comprising at least one gate electrode and at least one mold insulating in a second direction in the cell region and the connection region;
a common source layer on the mold structure;
a first insulating layer on the mold structure and the common source layer;
a channel structure connected to the common source layer by passing through the mold structure in the second direction in the cell region;
a cell plug in contact with at least one gate electrode by passing through the mold structure in the second direction in the connection region;
a contact structure including a first contact passing through the first insulating layer in the cell region and a second contact connected to the cell plug by passing through the first insulating layer in the connection region; and
a through electrode connecting the first contact to the peripheral circuit structure by passing through the mold structure in the second direction in the cell region.

19. The semiconductor device of claim 18, further comprising:
a first wiring layer connected to the peripheral circuit structure via the through electrode and the first contact; and
a second wiring layer connected to the peripheral circuit structure via the cell plug and the second contact.

20. The semiconductor device of claim 19, wherein the cell structure further comprises:
a peripheral circuit connection region surrounding the connection region; and
an input-output pad connecting the peripheral circuit connection region to the dummy block and overlapping the dummy block in the second direction.
